(19) United States
(12) Patent Application Publication
(10) Pub. No.: US 2018/0145258 A1
(43) Pub. Date: May 24, 2018

(54) ORGANIC SEMICONDUCTOR ELEMENT, COMPOUND, ORGANIC SEMICONDUCTOR COMPOSITION, ORGANIC SEMICONDUCTOR FILM, AND MANUFACTURING METHOD THEREOF

(71) Applicant: FUJIFILM Corporation, Tokyo (JP)

(72) Inventor: Fumiko TAMAKUNI, Kanagawa (JP)

(73) Assignee: FUJIFILM Corporation, Tokyo (JP)

(21) Appl. No.: 15/857,734

(22) Filed: Dec. 29, 2017

Related U.S. Application Data
(63) Continuation of application No. PCT/JP2016/067359, filed on Jun. 10, 2016.

(30) Foreign Application Priority Data
Jul. 7, 2015 (JP) 2015-136447

(51) Int. Cl. H01L 51/00; C08G 61/12

(52) U.S. Cl. CPC H01L 51/0036; C08G 61/124; H01L 51/0558; H01L 51/0043; H01L 51/0094; C08G 61/126

(57) ABSTRACT

The present invention relates to an organic semiconductor element (particularly, an organic thin film transistor) which exhibits high carrier mobility and can stably maintain carrier mobility even after long-term storage under high temperature and high humidity, a compound, an organic semiconductor composition using the compound, an organic semiconductor film, and a manufacturing method thereof.

The organic semiconductor element of the present invention includes an organic semiconductor layer containing a compound having a molecular weight of 2,000 or greater and a repeating unit represented by Formula (1).

D-A (1)

In Formula (1), A is an electron acceptor unit, D is an electron donor unit, and D and/or A have at least one monovalent organic group represented by Formula (1-1).

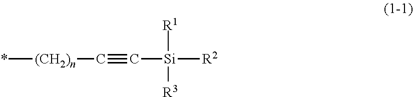

In Formula (1-1), n is an integer of 2 to 30, and R¹, R², and R³ each independently represent an alkyl group, an alkoxy group, an aryl group, or a heteroaryl group which may have a substituent, and * represents a bonding site to another structure.

### CROSS-REFERENCE TO RELATED APPLICATIONS

This application is a Continuation of PCT International Application No. PCT/JP2016/067359 filed on Jun. 10, 2016, which claims priority under 35 U.S.C. § 119(a) to Japanese Patent Application No. 2015-136447 filed on Jul. 7, 2015. The above application is hereby expressly incorporated by reference, in its entirety, into the present application.

### BACKGROUND OF THE INVENTION

### 1. Field of the Invention

The present invention relates to an organic semiconductor element, a compound, an organic semiconductor composition, an organic semiconductor film, and a manufacturing method thereof.

### 2. Description of the Related Art

Since light weight, low cost, and flexibility can be achieved, an organic thin film transistor (organic TFT) having an organic semiconductor film (organic semiconductor layer) is used in a device using a logic circuit such as a field effect transistor (FET), a radio frequency identifier (RFID: RF tag), or a memory used in liquid crystal displays or an organic electro luminescence (EL) display.

As a compound for forming such an organic semiconductor film, it is known that a polymer (so-called a “D-A-type polymer”) obtained by combining an electron donating (donor) unit and an electron accepting (acceptor) unit is useful.

For example, WO2013/150005A discloses a D-A-type polymer obtained by introducing an alkyl group having a silane terminal as a substituent.

For example, JP5494651B discloses a compound in which a silylethynyl group is directly connected to a conjugate plane of a D-A-type polymer as a D-A-type polymer used for a photoelectric conversion element.

### SUMMARY OF THE INVENTION

Recently, in view of improving the performance of the organic thin film transistor, further improvement of the carrier mobility of the organic thin film transistor is required.

Under such circumstances, the present inventors have conducted research on the organic thin film transistor using a D-A-type polymer obtained by introducing an alkyl group having a silane terminal as a substituent as the organic semiconductor compound as disclosed in WO2013/150005A and found that the carrier mobility can be further improved.

Recently, in accordance with popularization of the organic thin film transistors, the types of devices equipped with the organic thin film transistors are diversified, and the mounting ratio thereof is rising, and even after long-term storage under various circumstances, particularly under high temperature and high humidity, characteristics in that carrier mobility can be stably maintained are required.

An object of the present invention is to provide an organic semiconductor element (in particular, an organic thin film transistor) that exhibits high carrier mobility and can stably maintain carrier mobility even after long-term storage under high temperature and high humidity.

Another object of the present invention is to provide an organic semiconductor device, which exhibits high carrier mobility in a case of being used for an organic semiconductor layer of an organic semiconductor device (particularly an organic thin film transistor), a compound in which carrier mobility is stably maintained even after long-term storage under high temperature and high humidity, an organic semiconductor composition using the compound, an organic semiconductor film, and a manufacturing method thereof.

As a result of intensive studies on the above problems, the present inventors have found that a desired effect can be obtained by using a compound represented by Formula (1) described below, so as to conceive the present invention.

That is, the present inventors have found that the aforementioned objects can be achieved with the following configurations.

(1) An organic semiconductor element comprising an organic semiconductor layer containing a compound having a molecular weight of 2,000 or greater and a repeating unit represented by Formula (1).

(2) The organic semiconductor element according to (1), in which, in Formula (1), A has at least one structure selected from the group consisting of structures represented by Formulae (A-1) to (A-12), as a partial structure.

(3) The organic semiconductor element according to any one of (1) to (2), in which, in Formula (1), D represents a structure represented by Formula (D-1).

(4) The organic semiconductor element according to any one of (1) to (3), in which a repeating unit represented by Formula (1) is a repeating unit represented by any one of Formulae (2) to (5).

(5) The organic semiconductor element according to (2), in which Formulae (A-1) to (A-12) each have at least one of R^{A1} or R^{A2}, and at least one of R^{A1} or R^{A2} in each of the formulae is a monovalent group represented by Formula (1-1).

(6) The organic semiconductor element according to (4), in which Formulae (2) to (5) each have at least one of R^{A1} or R^{A2}, and at least one of R^{A1} or R^{A2} in each of the formulae is a monovalent group represented by Formula (1-1).

(7) The organic semiconductor element according to any one of (1) to (6), in which in Formula (1-1), the number of carbon atoms included in each of R¹, R², and R³ is 2 or greater.

(8) A compound having a molecular weight of 2,000 or greater and having a repeating unit represented by any one of Formulae (2) to (5), in which, Formulae (2) to (5) have at least one monovalent group represented by Formula (1-1).

(9) An organic semiconductor composition comprising a compound having a molecular weight of 2,000 or greater and including a repeating unit represented by Formula (1) and a solvent.

(10) An organic semiconductor film comprising a compound having a molecular weight of 2,000 or greater and a repeating unit represented by Formula (1).

(11) A method of manufacturing an organic semiconductor film, comprising: a coating step of coating a substrate with the organic semiconductor composition according to (9).

Hereinafter, the contents of the present invention will be specifically described. The constituents in the following description will be explained based on typical embodiments of the present invention, but the present invention is not limited to the embodiments.

In the present specification, the definition of the compound is used in the meaning of including salts thereof and ions thereof, in addition to the compound itself.

In the present specification, in a case where a plurality of substituents, linking groups, or the like (hereinafter, referred to as “substituents or the like) represented by a specific reference numeral exist, or in a case where a plurality of substituents or the like are defined at the same time, the respective substituents or the like may be identical to or different from each other. The same is also applied to the definition of the number of substituents or the like.

Unless described otherwise, in a case where a plurality of substituents or the like are close to each other (particularly, adjacent to each other), this means that the substituents or the like are linked to each other or condensed to each other to form a ring.

In the present specification, substituents or the like in which substitution or unsubstitution is not defined mean the substituents or the like may further have a substituent without deteriorating the desired effect. The same is applied to a compound in which substitution or unsubstitution is not defined.

In the present specification, the numerical range expressed by using “to” means a range including numerical values described before and after “to” as a lower limit value and an upper limit value.

According to the present invention, it is possible to provide an organic semiconductor element (in particular, an organic thin film transistor) that exhibits high carrier mobility and can stably maintain carrier mobility even after long-term storage under high temperature and high humidity.

According to the present invention, it is possible to provide an organic semiconductor device, which exhibits high carrier mobility in a case of being used for an organic semiconductor layer of an organic semiconductor device (particularly an organic thin film transistor), a compound in which carrier mobility is stably maintained even after long-term storage under high temperature and high humidity, an organic semiconductor composition using the compound, an organic semiconductor film, and a manufacturing method thereof.

### BRIEF DESCRIPTION OF THE DRAWINGS

FIG. 1 is a cross-sectional view schematically illustrating a bottom contact type organic thin film transistor according to one embodiment of the present invention.

FIG. 2 is a cross-sectional view schematically illustrating a top contact type organic thin film transistor according to one embodiment of the present invention.

### DESCRIPTION OF THE PREFERRED EMBODIMENTS

[Organic Semiconductor Element]

The organic semiconductor element (particularly an organic thin film transistor) of the present invention includes an organic semiconductor layer (organic semiconductor film) containing a compound having a molecular weight of 2,000 or greater and a repeating unit represented by Formula (1).

D-A (1)

In Formula (1), A represents an electron acceptor unit including a partial structure having at least one of a sp2 nitrogen atom, a carbonyl group, or a thiocarbonyl group in a ring structure, D represents an electron donor unit including a divalent aromatic heterocyclic group having at least one of a N atom, an O atom, a S atom, or a Se atom in a ring structure or a divalent aromatic hydrocarbon group consisting of a fused ring structure having two or more rings as a partial structure, and D and/or A has at least one monovalent group represented by Formula (1-1).

The electron acceptor unit refers to a constitutional unit having electron acceptability and examples thereof include a π electron-deficient heterocyclic unit such as phthalimide.

The electron donor unit refers to a constitutional unit having electron donating properties, and examples thereof include a n electron-rich heterocyclic unit such as thiophene.

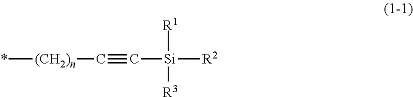

In Formula (1-1), n is an integer of 2 to 30, and R¹, R², and R³ each independently represent an alkyl group, an alkoxy group, an aryl group, or a heteroaryl group which may have a substituent, and * represents a bonding site to another structure.

The compound having a repeating unit represented by Formula (1) exhibits barrier properties (hydrophobicity) and also has excellent solubility to an organic solvent due to steric hindrance by Si substituent at a silylethynyl group terminal by introducing an alkyl group having a specific number of carbon atoms having a silylethynyl group terminal represented by Formula (1-1) to the main-chain skeleton formed from an electron donor unit and an electron acceptor unit. It is assumed that the concentration of the organic semiconductor compound in the organic semiconductor layer can be increased, the crystallization of the organic semiconductor compound in the organic semiconductor layer to be formed easily proceeds, the organic semiconductor element has excellent carrier mobility and stably maintains the carrier mobility even after long-term storage under high temperature and high humidity (hereinafter also referred to as “temporal stability under high temperature and high humidity”).

Hereinafter, the configuration of the present invention is described below.

[Compound Having Molecular Weight of 2,000 or Greater and Having Repeating Unit Represented by Formula (1)]

The compound having a molecular weight of 2,000 or greater and a repeating unit represented by Formula (1) (hereinafter, simply referred to as a “specific compound”) can be used as an organic semiconductor layer (organic semiconductor film) in an organic semiconductor element such as an organic thin film transistor.

<Repeating Unit Represented by Formula (1)>

### (Electron Acceptor Unit)

In Formula (1), A represents an electron acceptor unit including a partial structure having at least one of a sp2 nitrogen atom, a carbonyl group, or a thiocarbonyl group in a ring structure.

A preferably has at least one structure selected from the group consisting of structures represented by Formulae (A-1) to (A-12) as a partial structure, and A is more preferably a structure represented by at least one selected from the group consisting of Formulae (A-1) to (A-12).

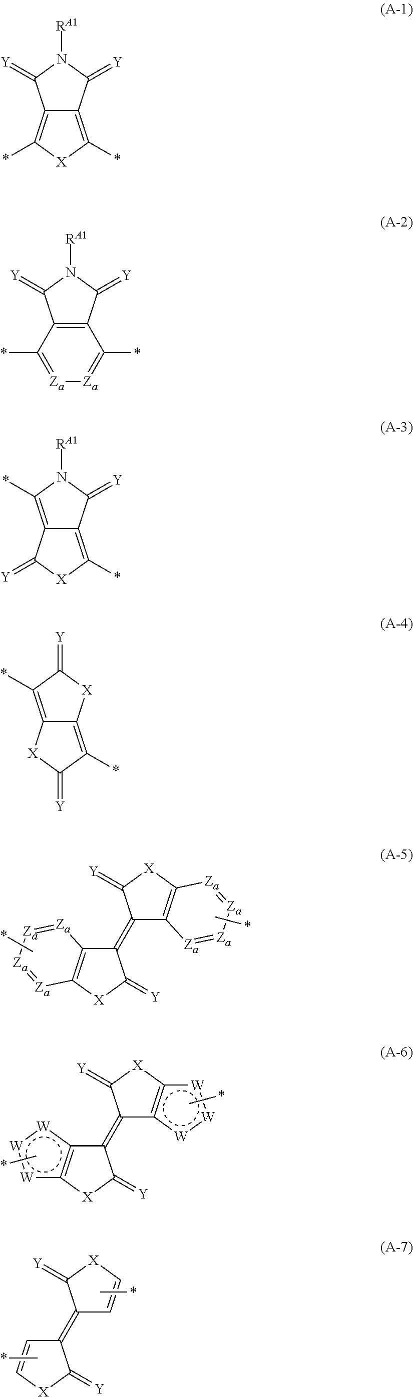

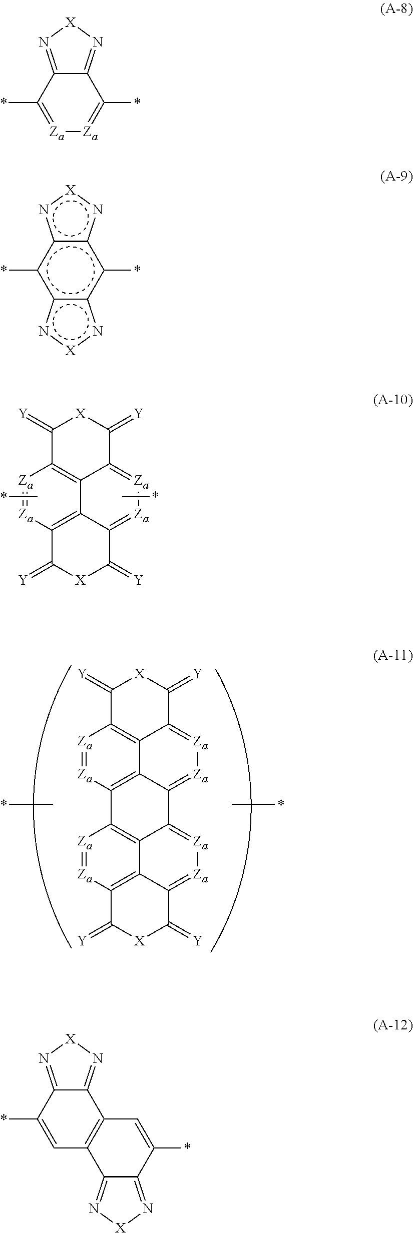

In Formulae (A-1) to (A-12), X's each independently represent an O atom, a S atom, a Se atom, or NR^{A1}, Y's each independently represent an O atom or a S atom, Zₐ's each independently represent CR^{A2} or a N atom, W's each independently represent C(R^{A2})₂, NR^{A1}, a N atom, CR^{A2}, an O atom, a S atom, or a Se atom, R^{A1}'s each independently represent an alkyl group that may contain at least one of —O—, —S—, or —NR^{A3}—, a monovalent group represented by Formula (1-1), or a bonding site to another structure, R^{A2}'s each independently represent an alkyl group that may contain at least one of —O—, —S—, or —NR^{A3}—, a hydrogen atom, a halogen atom, a monovalent group represented by Formula (1-1), or a bonding site to another structure, *'s each independently represent a bonding site to another structure, and R^{A3} represents a hydrogen atom or a substituent.

In Formulae (A-1) to (A-12), X's each independently represent an O atom, a S atom, a Se atom, or NR^{A1}, and NR^{A1} is preferable.

Y's each independently represent an O atom or a S atom, and an O atom is preferable.

Zₐ's each independently represent CR^{A2} or a N atom, and CR^{A2} is preferable.

W's each independently represent C(R^{A2})₂, NR^{A1}, a N atom, CR^{A2}, an O atom, a S atom, or a Se atom, and C(R^{A2})₂, CR^{A2}, or a S atom is preferable.

R^{A1}'s each independently represent an alkyl group that may contain at least one of —O—, —S—, or —NR^{A3}—, a monovalent group represented by Formula (1-1), or a bonding site to another structure, and a monovalent group represented by Formula (1-1) is preferable.

In a case where R^{A1} represents an alkyl group, an alkyl group having 2 to 30 carbon atoms is preferable, and an alkyl group having 8 to 25 carbon atoms is more preferable. The alkyl group may have a linear shape or a branched shape. At least one of —O—, —S—, or —NR^{A3}— may be contained in the alkyl group.

A bonding site to another structure in R^{A1} is a bonding site to another structure represented by * in Formulae (A-1) to (A-12).

R^{A2}'s each independently represent an alkyl group that may contain at least one of —O—, —S—, or —NR^{A3}—, a hydrogen atom, a halogen atom, a monovalent group represented by Formula (1-1), or a bonding site to another structure, and a hydrogen atom or a bonding site to another structure is preferable.

In a case where R^{A2} represents an alkyl group, an alkyl group having 2 to 30 carbon atoms is preferable, and an alkyl group having 8 to 25 carbon atoms is more preferable. The alkyl group may have a linear shape or a branched shape. At least one of —O—, —S—, or —NR^{A3}— may be contained in the alkyl group.

In a case where R^{A2} represents a halogen atom, a F atom, a Cl atom, a Br atom, or an I atom is preferable, and a F atom is more preferable.

A bonding site to another structure in R^{A2} is a bonding site to another structure represented by * in Formulae (A-1) to (A-12).

R^{A3} represents a hydrogen atom or a substituent. The substituent represents an alkyl group (preferably a linear or branched alkyl group having 1 to 10 carbon atoms), a halogen atom (preferably a F atom, a Cl atom, a Br atom, or an I atom) or an aryl group (preferably an aryl group having 6 to 20 carbon atoms). Among these, a hydrogen atom or an alkyl group is preferable.

With respect to the specific compound, A in Formula (1) preferably has at least one structure selected from the group consisting of structures represented by Formulae (A-1) to (A-12) as a partial structure, more preferably has at least one structure selected from the group consisting of structures represented by Formulae (A-1), (A-3), (A-4), (A-5), (A-6), (A-8), and (A-12), and (A-12), as a partial structure, even more preferably has at least one structure selected from the group consisting of structures represented by Formulae (A-1), (A-3), (A-5), (A-6), and (A-12), as a partial structure, particularly preferably has at least one structure selected from the group consisting of structures represented by Formulae (A-1) and (A-3), as a partial structure, and most preferably has at least one structure selected from the group consisting of structures represented by Formula (A-3), as a partial structure.

According to the respective aspects, the specific compound is preferably an aspect in which A in Formula (1) has a structure represented by each formula to an aspect in which A in Formula (1) has a structure represented by each formula, as a partial structure.

An example in which a structure represented by Formulae (A-1) to (A-12) is provided below, but the present invention is not limited thereto. In the following structural formulae, R^{A1} has the same meaning as R^{A1} in Formulae A-1 to A-12, preferable aspects thereof are also the same, and

* represents a bonding site to another structure.

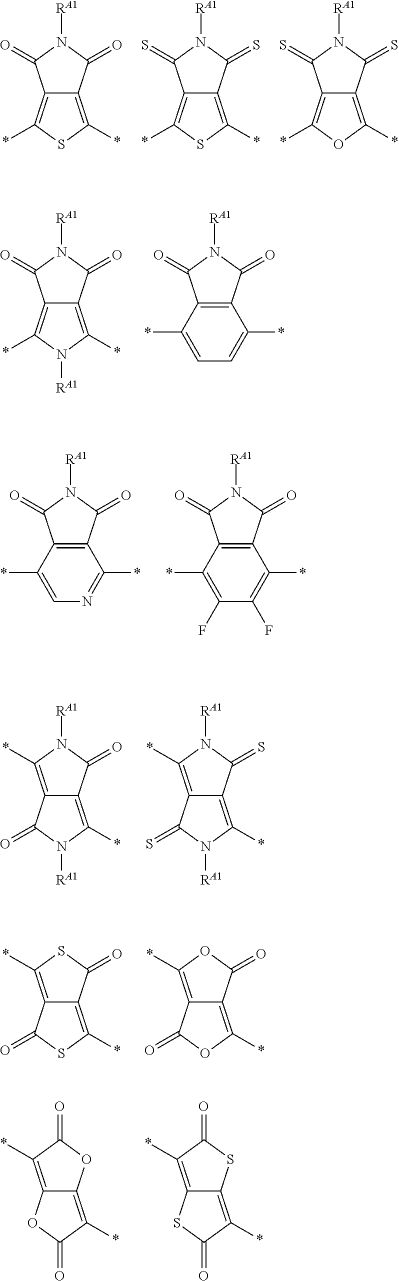

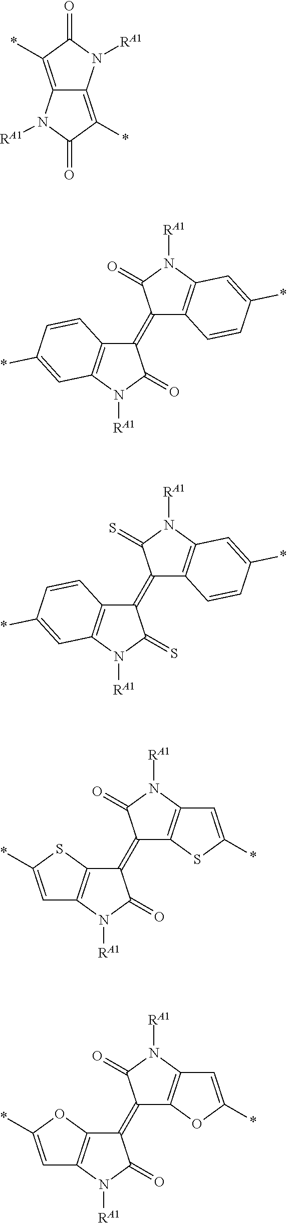

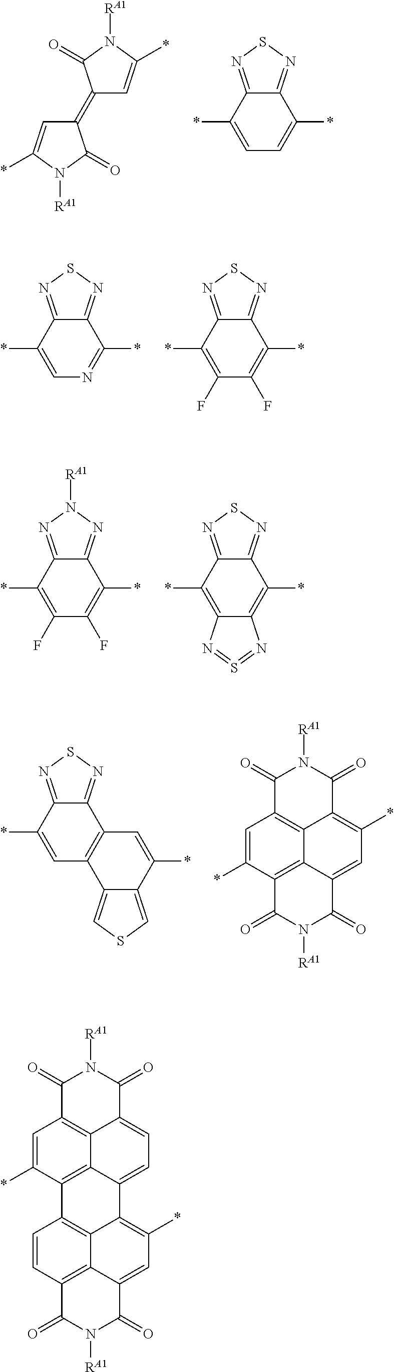

(Electron Donor Unit)

D represents an electron donor unit including a divalent aromatic heterocyclic group having at least one of a N atom, an O atom, a S atom, or a Se atom in a ring structure or a divalent aromatic hydrocarbon group consisting of a fused ring structure having two or more rings, as a partial structure.

The divalent aromatic heterocyclic group having at least one of a N atom, an O atom, a S atom, or a Se atom in a ring structure is preferably a divalent aromatic heterocyclic group having at least one S atom in a ring structure.

The divalent aromatic heterocyclic group may have a single ring or a fused ring structure having two or more rings, and preferably has a structure obtained by combining two or more divalent aromatic heterocyclic groups having single rings or a structure obtained by combining a divalent aromatic heterocyclic group having two or more single rings and a divalent aromatic heterocyclic group having one or more fused ring structures having two or more rings.

The divalent aromatic heterocyclic group may further have a substituent, and preferred substituents include a preferable alkyl group that may include at least one of —O—, —S—, or —NR^{D3}— (for example, an alkyl group having 1 to 30 carbon atoms or an alkoxy group having 1 to 30 carbon atoms is preferable, and an alkyl group having 1 to 30 carbon atoms is more preferable, and an alkyl group having 5 to 30 carbon atoms is further preferable), an alkenyl group (preferably having 2 to 30 carbon atoms), an alkynyl group (preferably having 2 to 30 carbon atoms), an aromatic hydrocarbon group (preferably having 6 to 30 carbon atoms), an aromatic heterocyclic group (preferably a 5-membered to 7-membered ring, and preferably an O atom, a N atom, a S atom, or a Se atom as a heteroatom), a halogen atom (a F atom, a Cl atom, a Br atom, or an I atom), and a monovalent group represented by Formula (1-1).

R^{D3} has the same meaning as R^{D3} in Formula (D-1), and preferable aspects thereof are also the same.

Examples of the divalent aromatic heterocyclic group are provided below, but the present invention is not limited thereto. In the structural formula, a hydrogen atom may be substituted. In a case where a hydrogen atom is substituted, examples of the substituent include substituents as described above (for example, an alkyl group that may contain at least one of —O—, —S— or —NR^{D3}—, an alkenyl group, an alkynyl group, an aromatic hydrocarbon group, an aromatic heterocyclic group, a halogen atom, or a group represented by Formula (1-1)). R^{D1} has the same meaning as R^{D1} in Formula (D-1) described below, preferable aspects are also the same, and * represents a bonding site to another structure.

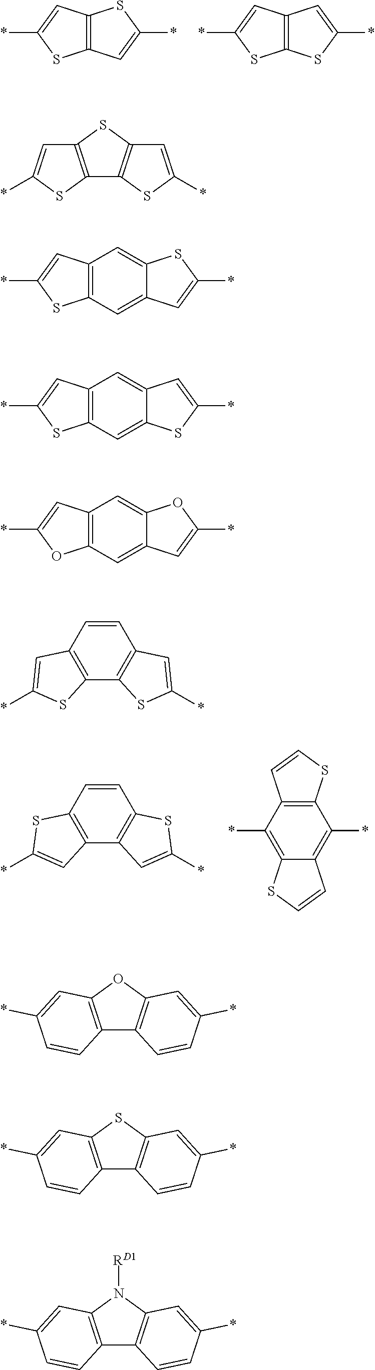

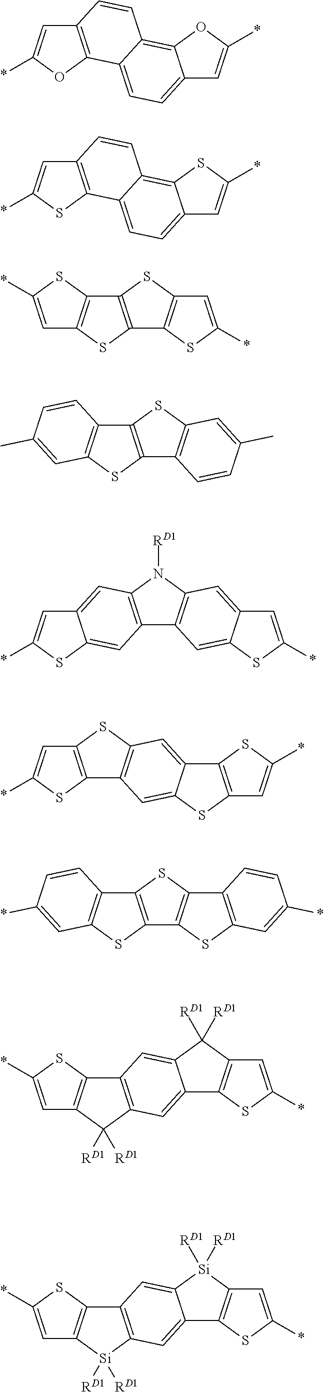

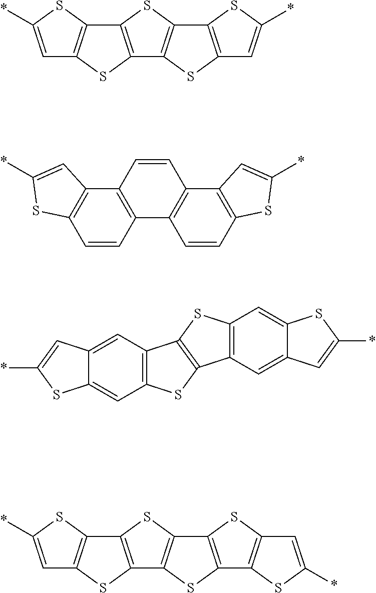 [SMILES: *c1cc2sc3c(sc4c5sc(*)cc5sc43)c2s1 ; *c1cc2c(ccc3c2ccc2c4cc(*)sc4ccc23)s1 ; *c1cc2cc3c(cc2s1)sc1c2cc4cc(*)sc4cc2sc31 ; *c1cc2sc3c(sc4c5sc6cc(*)sc6c5sc34)c2s1]

The divalent aromatic hydrocarbon group consisting of a fused ring structure having two or more rings is preferably an aromatic hydrocarbon group having 10 to 20 carbon atoms, more preferably a fluorene group, a naphthylene group, or a group obtained by removing two hydrogen atoms from the aromatic hydrocarbon in which three or four rings are fused, and even more preferably a fluorene group, a naphthylene group, or a group obtained by removing two hydrogen atoms from an anthracene ring, a phenanthrene ring, a chrysene ring, or a pyrene ring.

The aromatic hydrocarbon group may further have a substituent, and preferable examples of the substituent include an alkyl group that may contain at least one of —O—, —S—, or —NR^{D3}—, a halogen atom, or a monovalent group represented by Formula (1-1). Preferable examples of the alkyl group that may contain at least one of —O—, —S—, or —NR^{D3}— and the halogen atom are the same as those described for the divalent aromatic heterocyclic group.

R^{D3} has the same meaning as R^{D3} in Formula (D-1), and preferable aspects thereof are also the same.

In Formula (1), D is preferably a structure represented by Formula (D-1).

In Formula (D-1) and Formulae (2) to (5) described below, each repeating unit and M described above are bonded to each other at the bonding axis in a rotatable manner. That is, for example, in the description of Formulae (D-1) and (2) to (5), it is preferable that a repeating unit of a 5-membered ring that links p items and a repeating unit of a 5-membered ring that links q items are wound around each other in a reverse direction. However, in Formulae (D-1) and Formulae (2) to (5) to be described below also have a structure in which repeating units are wound around each other in the same direction.

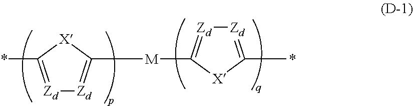

In Formula (D-1), X″s each independently represent an O atom, a S atom, a Se atom, or NR^{D1}, Z_{d}'S each independently represent an N atom or CR^{D2}, R^{D1}'s each independently represent a monovalent organic group that may be a monovalent group represented by Formula (1-1), R^{D2}'s each independently represent a hydrogen atom or a monovalent organic group that may be a monovalent group represented by Formula (1-1), M represents a single bond, a divalent aromatic heterocyclic group, a divalent aromatic hydrocarbon group, an alkenylene group, an alkynylene group, or a divalent group obtained by combining these, p and q each independently represent an integer of 0 to 4, and *'s each independently represent a bonding site to another structure. M represents an alkyl group that may contain at least one of —O—, —S—, or —NR^{D3}— as a substituent or a monovalent group represented by Formula (1-1), and R^{D3} represents a hydrogen atom or a substituent.

In Formula D-1, X″s each independently represent an O atom, a S atom, a Se atom, or NR^{D1}, preferably an O atom or a S atom, and more preferably a S atom.

Z_{d}'s each independently represent a N atom or CR^{D2} and more preferably represents CR^{D2}.

R^{D1}'s each independently represent a monovalent organic group, and the substituent is preferably an alkyl group that may include at least one of —O—, —S—, or —NR^{D3}— (for example, preferably an alkyl group having 1 to 30 carbon atoms or an alkoxy group having 1 to 30 carbon atoms, more preferably an alkyl group having 1 to 30 carbon atoms, and even more preferably an alkyl group having 5 to 30 carbon atoms), an alkynyl group (preferably having 2 to 30 carbon atoms), an alkenyl group (preferably having 2 to 30 carbon atoms), an aromatic hydrocarbon group (preferably having 6 to 30 carbon atoms), an aromatic heterocyclic group (preferably a 5-membered to 7-membered ring, and preferably an O atom, N atom, S atom, or Se atom as the heteroatom) a halogen atom (preferably an F atom, a Cl atom, a Br atom or an I atom, more preferably an F atom or a Cl atom, and particularly preferably an F atom), or a monovalent group represented by Formula (1-1), and more preferably an alkyl group which may contain at least one of —O—, —S—, or —NR^{D3-}, a halogen atom, or a monovalent group represented by Formula (1-1).

R^{D2}'s each independently represent a hydrogen atom, a monovalent organic group, and the substituent is preferably a hydrogen atom, an alkyl group that may include at least one of —O—, —S—, or —NR^{D3}— (for example, an alkyl group having 1 to 30 carbon atoms or an alkoxy group having 1 to 30 carbon atoms is preferable, an alkyl group having 1 to 30 carbon atoms is more preferable, and an alkyl group having 5 to 30 carbon atoms is even more preferable), an alkynyl group (preferably having 2 to 30 carbon atoms), an alkenyl group (preferably having 2 to 30 carbon atoms), an aromatic hydrocarbon group (preferably having 6 to 30 carbon atoms), an aromatic heterocyclic group (preferably a 5-membered to 7-membered ring, and preferably an O atom, N atom, S atom, or Se atom as the heteroatom), a halogen atom (preferably an F atom, a Cl atom, a Br atom or an I atom, more preferably an F atom or a Cl atom, and particularly preferably an F atom), or a monovalent group represented by Formula (1-1), and more preferably an alkyl group which may contain at least one of —O—, —S—, or —NR^{D3}—, a hydrogen atom, a halogen atom, or a monovalent group represented by Formula (1-1).

M represents a single bond, a divalent aromatic heterocyclic group, a divalent aromatic hydrocarbon group, an alkenylene group, an alkynylene group, or a divalent group obtained by combining these. M may have an alkyl group that may contain at least one of —O—, —S—, or —NR^{D3}— or a monovalent group represented by Formula (1-1), as a substituent.

R^{D3} represents a hydrogen atom or a substituent. The substituent represents an alkyl group (preferably a linear or branched alkyl group having 1 to 10 carbon atoms), a halogen atom (preferably a F atom, a Cl atom, a Br atom, or an I atom) or an aryl group (preferably an aryl group having 6 to 20 carbon atoms). Among these, a hydrogen atom or an alkyl group is preferable.

The divalent aromatic heterocyclic group in M may have a single ring or may have a fused ring structure having two or more rings. Examples of the divalent aromatic heterocyclic group preferably used in the present invention are the same as those of the above divalent aromatic heterocyclic group having a fused ring structure having two or more rings.

The divalent aromatic hydrocarbon group in M is preferably an aromatic hydrocarbon group having 6 to 20 carbon atoms, more preferably a phenylene group, a biphenylene group, a fluorene group, a naphthylene group, or a group obtained by removing two hydrogen atoms from aromatic hydrocarbon in which three or four rings are fused, and even more preferably a fluorene group, a naphthylene group, an anthracene ring, a phenanthrene ring, a chrysene ring, or a group obtained by removing two or more hydrogen atoms from a pyrene ring.

The divalent aromatic heterocyclic group or the divalent hydrocarbon group in M may further have a substituent, and examples of the preferred substituents include a preferable alkyl group that may include at least one of —O—, —S—, or —NR^{D3}— (for example, an alkyl group having 1 to 30 carbon atoms or an alkoxy group having 1 to 30 carbon atoms is preferable, an alkyl group having 1 to 30 carbon atoms is more preferable, and an alkyl group having 5 to 30 carbon atoms is even more preferable), and a halogen atom (a F atom, a Cl atom, a Br atom, or an I atom is preferable, and a F atom is particularly preferable), in addition to a monovalent group represented by Formula (1-1).

An alkenylene group in M is preferably an alkenylene group having 2 to 10 carbon atoms, more preferably an alkenylene group having 2 to 4 carbon atoms, and even more preferably an ethenylene group.

An alkynylene group in M is preferably an alkynylene group having 2 to 10 carbon atoms, more preferably an alkynylene group having 2 to 4 carbon atoms, and even more preferably an ethynylene group.

p and q each independently represent an integer of 0 to 4, preferably an integer of 1 to 3, and more preferably an integer of 1 to 2. It is preferable that p and q have the same value. It is preferable that p+q is 2 to 4.

Examples of the structure represented by Formula (D-1) are provided below, but the present invention is not limited to the following examples. In the structural formula, a hydrogen atom may be substituted. In a case where a hydrogen atom is substituted, examples of the substituent include substituents as described above (for example, an alkyl group that may contain at least one of —O—, —S—, or —NR^{D3}—, or a group represented by Formula (1-1)). R^{D1} has the same meaning as R^{D1} in Formula (D-1) described above, preferable aspects are also the same, and * represents a bonding site to another structure.

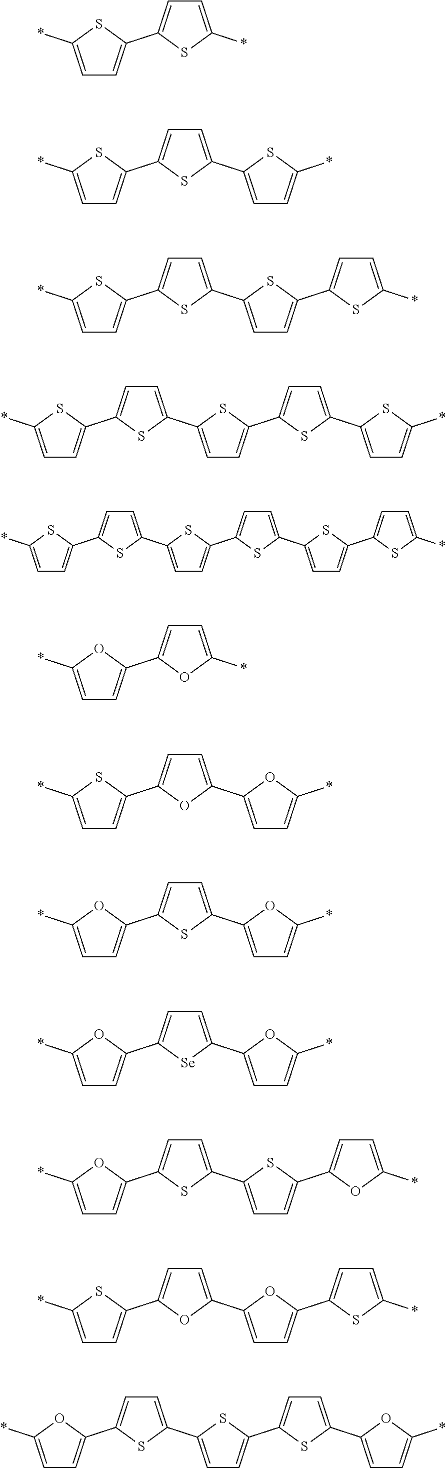

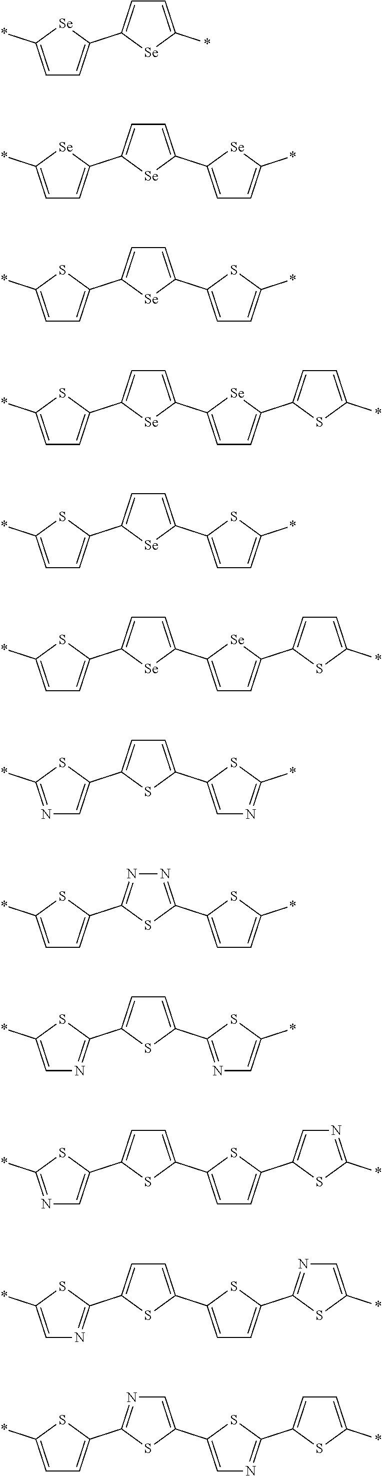

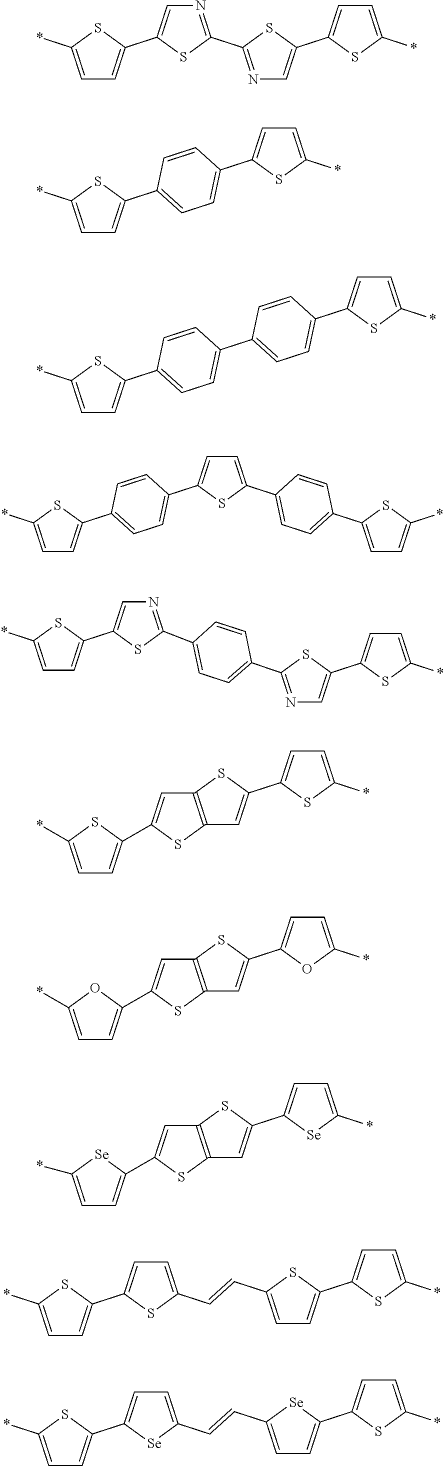

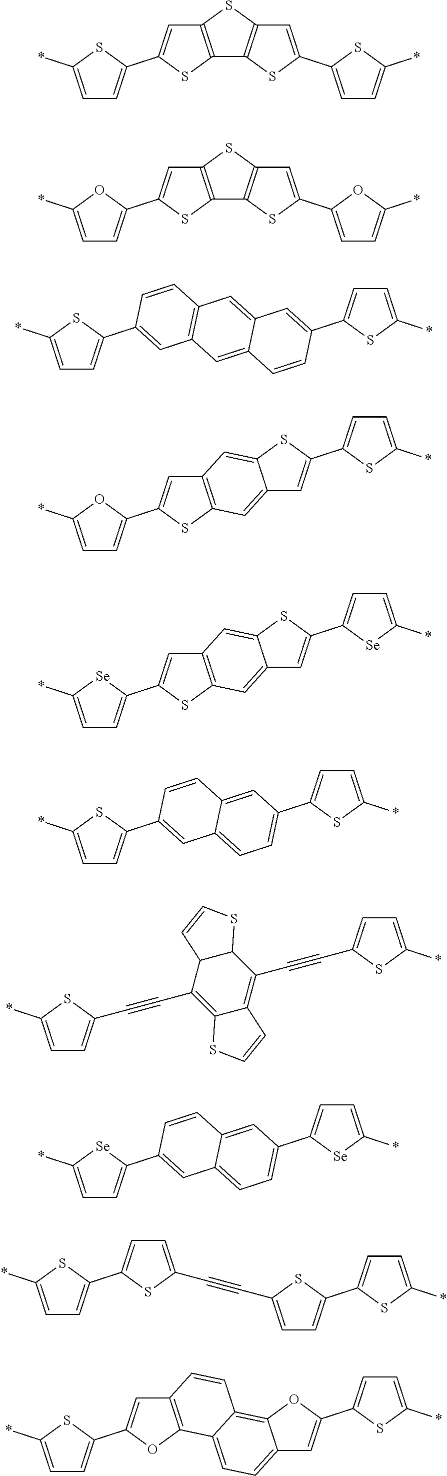

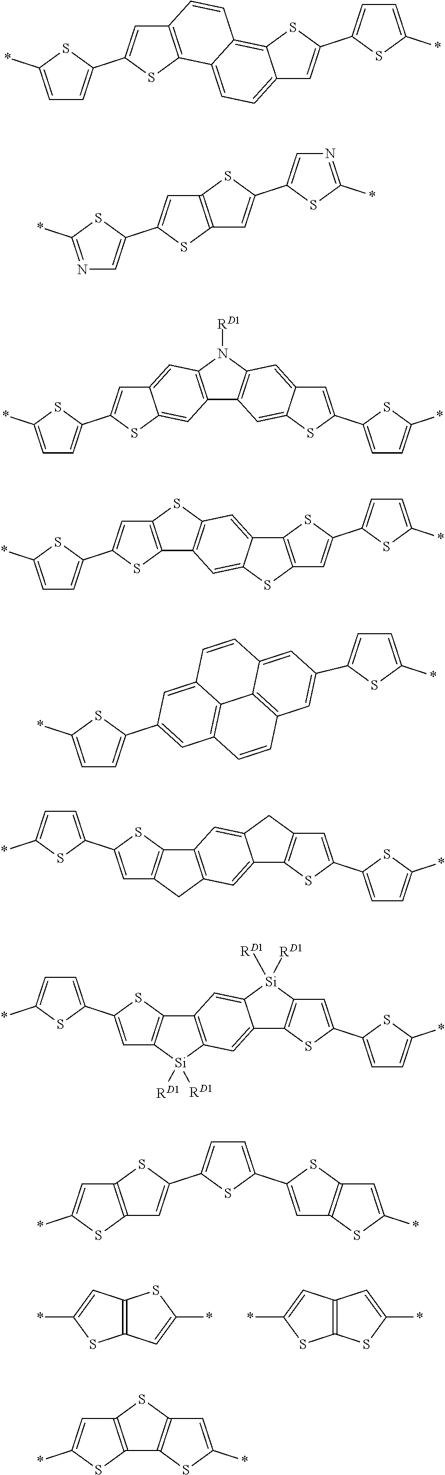

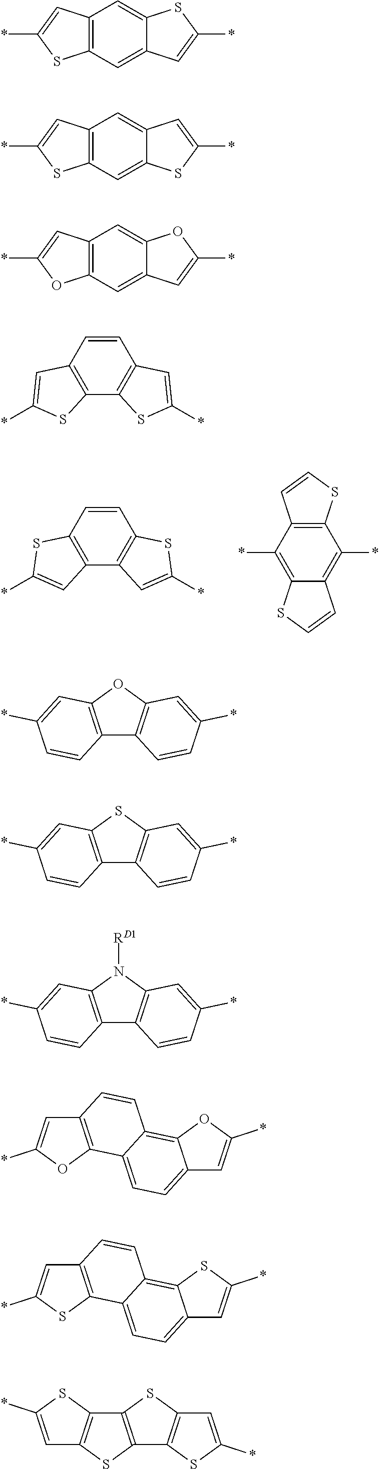

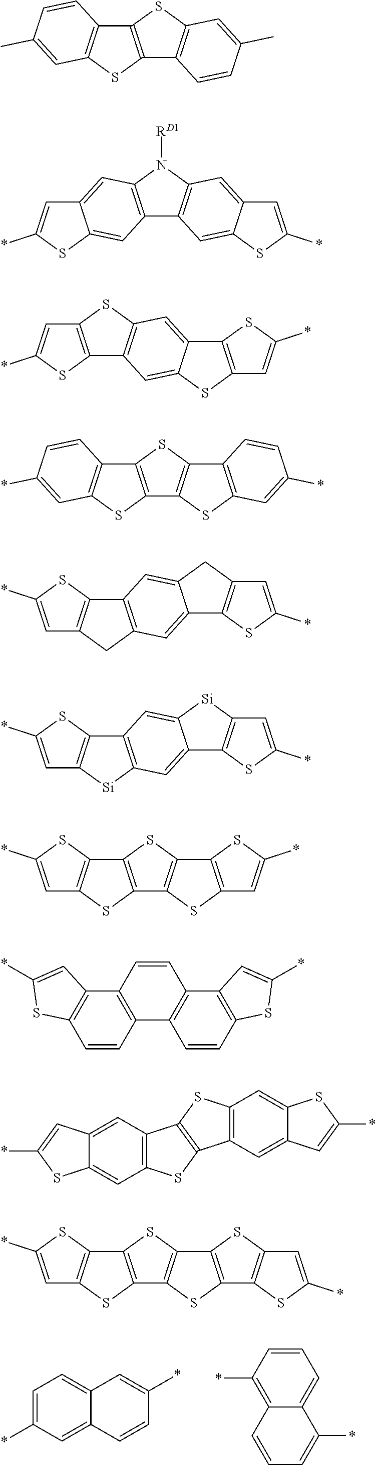

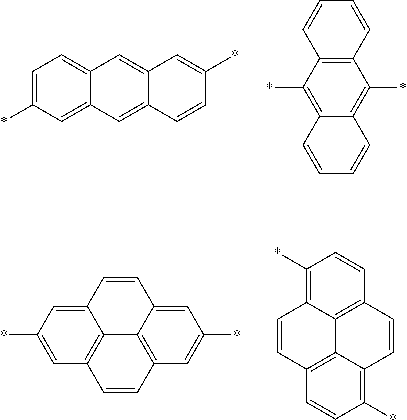

In Formula (1), D and/or A has at least one monovalent group represented by Formula (1-1).

The number of monovalent groups represented by Formula (1-1) in the repeating unit represented by Formula (1) is preferably 1 to 4 and more preferably 1 or 2.

In Formula (1-1), n is an integer of 2 to 30. In view of excellent carrier mobility and temporal stability under high temperature and high humidity, n is preferably an integer of 3 or greater and more preferably an integer of 4 or greater. In view of the crystallinity of the specific compound, n is preferably 20 or less and more preferably 15 or less.

R¹, R², and R³ each independently represent an alkyl group, an alkoxy group, an aryl group or a heteroaryl group that may have a substituent.

The alkyl group is preferably an alkyl group having 1 to 20 carbon atoms, more preferably an alkyl group having 1 to 10 carbon atoms. Since at least one of carrier mobility and temporal stability under high temperature and high humidity is excellent, an alkyl group having 2 to 10 carbon atoms is more preferable, and an alkyl group having 3 to 8 carbon atoms is particularly preferable. The alkyl group may have any one of a linear shape, a branched shape, and a circular shape, but is preferably a linear or branched alkyl group and more preferably a branched alkyl group.

The alkoxy group is preferably an alkoxy group having 1 to 20 carbon atoms and more preferably an alkoxy group having 2 to 10 carbon atoms. An alkoxy group may have any one of a linear shape, a branched shape, and a circular shape, but is preferably a linear or branched alkoxy group and more preferably a branched alkoxy group.

The aryl group is preferably an aryl group having 6 to 20 carbon atoms and more preferably an aryl group having 6 to 10 carbon atoms.

The heteroaryl group is preferably a heteroaryl group having 4 to 20 carbon atoms, more preferably a heteroaryl group having 4 to 10 carbon atoms, and even more preferably a heteroaryl group having 4 to 6 carbon atoms.

Among these, R¹, R², and R³ are preferably an alkyl group, an alkoxy group, or an aryl group and more preferably an alkyl group.

Examples of the substituent that may be included in R¹, R², and R³ include ether, thioether, or halogen (a F atom, a Cl atom, a Br atom, or an I atom is preferable, and a F atom is more preferable).

Formula (1-1) bonded to another structure at the position of *.

Since at least one of carrier mobility and temporal stability under high temperature and high humidity is excellent, the number of carbon atoms included in R¹, R², and R³ is preferably 2 or greater and more preferably 3 or greater. The upper limit is not particularly limited, but examples of the upper limit include 30 or less. Particularly, R¹, R², and R³ are preferably an alkyl group having 2 or more carbon atoms (preferably having 20 or less carbon atoms).

The monovalent group represented by Formula (1-1) preferably has A (electron acceptor unit) in Formula (1) and is more preferably bonded to a nitrogen atom existing in A in Formula (1).

Since at least one of carrier mobility and temporal stability under high temperature and high humidity is more excellent, it is preferable that Formulae (A-1) to (A-12) have at least one of R^{A1} or R^{A2}, and at least one of R^{A1} or R^{A2} in each formula is preferably a monovalent group represented by Formula (1-1).

In view of the crystallinity of the specific compound, it is preferable that A in Formula (1) has symmetry of C₂, C₂ᵥ, or C₂ₕ.

In view of the crystallinity of the specific compound, it is preferable that D in Formula (1) has symmetry of C₂, C₂ᵥ, or C₂ₕ.

In view of the crystallinity of the specific compound, in Formula (1), it is preferable that the symmetry of A is C₂, C₂ᵥ, or C₂ₕ, and it is more preferable that the symmetry of D is C₂, C₂ᵥ, or C₂ₕ. With respect to the symmetry, “Molecular Symmetry and Group Theory” (written by Masao Nakazaki, Tokyo Kagaku Dojin Co., Ltd.) is referred to.

Particularly, the specific compound preferably has a structure constituted of an electron acceptor unit having at least one structure selected from the group consisting of structures represented by Formulae (A-1), (A-3), (A-4), (A-5), (A-6), (A-8), and (A-12) as a partial structure (preferably, having structures represented by Formula (A-1), (A-3), (A-4), (A-5), (A-6), (A-8), and (A-12)) and an electron donor unit represented by Formula (D-1) as a main-chain skeleton (a D-A-type polymer skeleton of Formula (1)), and the monovalent group represented by Formula (1-1) is preferably introduced into A in the main-chain skeleton, that is, into an electron acceptor unit and is more preferably bonded to the nitrogen atom existing in A in the main-chain skeleton.

In a case where the specific compound has such a structure, the monovalent group represented by Formula (1-1) is aligned so as to protrude to the outside with respect to the conjugate plane formed by the main-chain skeleton represented by Formula (1), and the conjugate leveling of the main-chain skeleton is hardly broken. As a result, packing between the main-chain molecules in the organic semiconductor layer becomes better, and the carrier mobility becomes excellent.

<Repeating Unit Represented by Formulae (2) to (5)>

The repeating unit represented by Formula (1) is preferably a repeating unit represented by any one of Formulae (2) to (5), more preferably a repeating unit represented by any one of Formulae (2) to (4), even more preferably a repeating unit represented by any one of Formula (2) or (3), and particularly preferably a repeating unit represented by Formula (3).

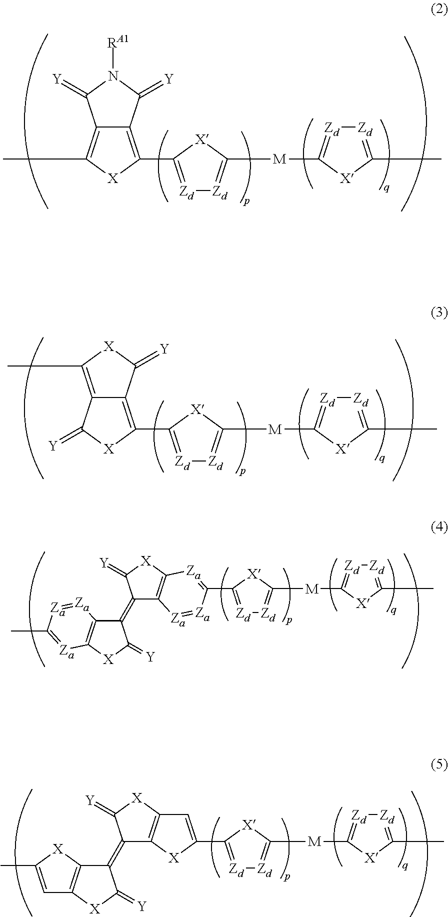

In Formulae (2) to (5), X's each independently represent an O atom, a S atom, a Se atom, or NR^{A1}, Y's each independently represent an O atom or a S atom, Zₐ's each independently represent CR^{A2} or a N atom, R^{A1}'s each independently represent an alkyl group that may contain at least one of —O—, —S—, or —NR^{A3}—, a monovalent group represented by Formula (1-1), or a bonding site to another structure, R^{A2}'s each independently represent an alkyl group that may contain at least one of —O—, —S—, or —NR^{A3}—, a hydrogen atom, a halogen atom, a monovalent group represented by Formula (1-1), or a bonding site to another structure, R^{A3} represents a hydrogen atom or a substituent, X″s each independently represent an O atom, a S atom, a Se atom, or NR^{D1}, Z_{d}'s each independently represent an N atom or CR^{D2}, R^{D1}'s each independently represent a monovalent organic group that may be a monovalent group represented by Formula (1-1), R^{D2}'s each independently represent a hydrogen atom or a monovalent organic group that may be a monovalent group represented by Formula (1-1), M represents a single bond, a divalent aromatic heterocyclic group, a divalent aromatic hydrocarbon group, an alkenylene group, an alkynylene group, or a divalent group obtained by combining these, and p and q each independently represent an integer of 0 to 4. M represents an alkyl group that may contain at least one of —O—, —S—, or —NR^{D3}— as a substituent or a monovalent group represented by Formula (1-1), and R^{D3} represents a hydrogen atom or a substituent.

In Formulae (2) to (5), X, Y, Zₐ, R^{A1}, R^{A2}, and R^{A3} have the same meaning as X, Y, Zₐ, R^{A1}, R^{A2}, and R^{A3} in Formulae (A-1) to (A-12), respectively, and preferable aspects thereof are also the same.

In Formulae (2) to (5), X′, Z_{d}, R^{D1}, R^{D2}, M, p, and q have the same meaning as X′, Z_{d}, R^{D1}, R^{D2}, M, p, and q in Formula (D-1), respectively, and preferable aspects thereof are also the same.

Since at least one of carrier mobility and temporal stability under high temperature and high humidity is more excellent, it is preferable that Formulae (2) to (5) have at least one of R^{A1} or R^{A2}, and at least one of R^{A1} or R^{A2} in each formula is preferably a monovalent group represented by Formula (1-1).

<<Preferable Aspects of Specific Compound>>

In the specific compound, the content of the repeating unit represented by Formula (1) is preferably 60 to 100 mass %, more preferably 80 to 100 mass %, and even more preferably 90 to 100 mass % with respect to the total mass of the specific compound. It is particularly preferable that the constitutional repeating unit is substantially formed only with the repeating unit represented by Formula (1). The expression “the repeating unit is substantially formed only with the constitutional repeating unit represented by Formula (1)” means that the content of the repeating unit represented by Formula (1) is 95 mass % or greater, preferably 97 mass % or greater, and more preferably 99 mass % or greater.

In a case where the content of the repeating unit represented by Formula (1) is in the range above, an organic semiconductor having excellent carrier mobility can be obtained.

The specific compound may include a repeating unit represented by Formula (1) singly or two or more kinds thereof may be included.

The specific compound is a compound having two or more repeating units represented by Formula (1) and may be an oligomer in which the number “n” of repeating units is two to nine or may be a polymer in which the number “n” of repeating units is 10 or greater. Among these, a polymer in which the number “n” of repeating units is 10 or greater is preferable, in view of carrier mobility and obtainable physical properties of the organic semiconductor film.

In view of carrier mobility, the molecular weight of the compound having a repeating unit represented by Formula (1) is 2,000 or greater, preferably 5,000 or greater, more preferably 10,000 or greater, even more preferably 20,000 or greater, and particularly preferably 30,000 or greater. In view of solubility, the molecular weight is preferably 1,000,000 or less, more preferably 300,000 or less, even more preferably 150,000 or less, and particularly preferably 100,000 or less.

According to the present invention, in a case where the compound has a molecular weight distribution, the molecular weight of this compound means a weight-average molecular weight.

According to the present invention, the weight-average molecular weight and the number-average molecular weight can be measured by gel permeation chromatography (GPC) method, and can be obtained in terms of standard polystyrene. Specifically, for example, in GPC, HLC-8121 GPC (manufactured by Tosoh Corporation) is used, two columns of TSKgel GMH_{HR}-H (20) HT (manufactured by Tosoh Corporation, 7.8 mm ID×30 cm) are used as the column, 1,2,4-trichlorobenzene is used as an eluent. An infrared (IR) detector is used with conditions of a sample concentration of 0.02 mass %, a flow rate of 1.0 ml/min, a sample injection amount of 300 μl, and a measurement temperature of 160° C. The calibration curve is manufactured from 12 samples of “standard sample TSK standard, polystyrene”: “F-128”, “F-80”, “F-40”, “F-20”, “F-10”, “F-4”, “F-2”, “F-1”, “A-5000”, “A-2500”, “A-1000”, and “A-500” manufactured by Tosoh Corporation.

Only one kind of specific compound may be contained or two or more kinds of specific compounds may be contained in an organic semiconductor layer described below, an organic semiconductor film described below, or an organic semiconductor composition described below. However, in view of alignment properties and carrier mobility, only one kind thereof is preferably used.

The structure of the terminal of the specific compound is not particularly limited, and depends on the existence of other constitutional units, kinds of base substances used in the synthesis, and kinds of a quench agent (reaction terminator) used in the synthesis. Here, examples thereof include a hydrogen atom, a hydroxy group, a halogen atom, an ethylenically unsaturated group, and an alkyl group.

A method of synthesizing a specific compound is not particularly limited, and may be synthesized with reference to well-known methods. For example, with reference to JP2010-527327A, JP2007-516315A, JP2014-515043A, JP2014-507488A, JP2011-501451A, JP2010-18790A, WO2012/174561A, JP2011-514399A, and JP2011-514913A, synthesis may be performed by synthesizing a precursor of an electron acceptor unit and a precursor of an electron donor unit and performing cross-coupling reactions such as Suzuki coupling and Stille coupling of each precursor.

Hereinafter, preferable specific examples of the preferable repeating unit represented by Formula (1) are provided, but the present invention is not limited to the examples below.

In the following exemplified compounds, “TIPS” is a triisopropylsilyl group, “Hex” is a hexyl group, “TMS” is a trimethylsilyl group, “TBDPS” is a tert-butyldiphenylsilyl group, “EtO” is an ethoxy group, “TES” is a triethylsilyl group, “Ph” is a phenyl group, and “Cy” is a cyclohexyl group.

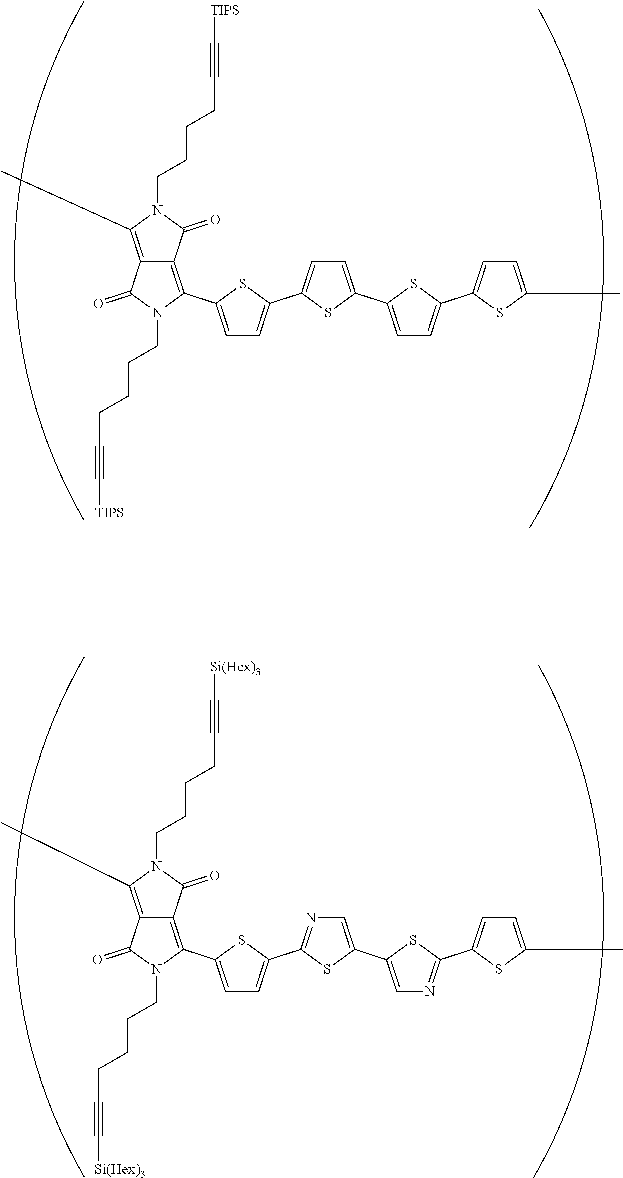

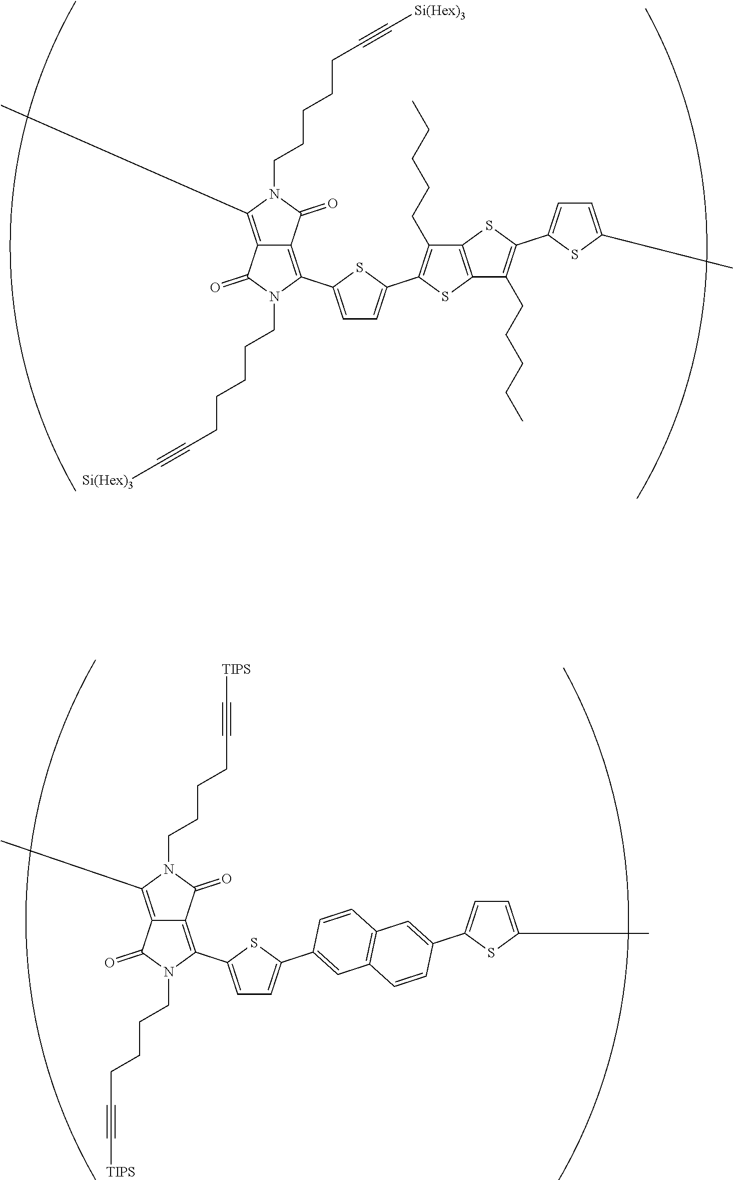

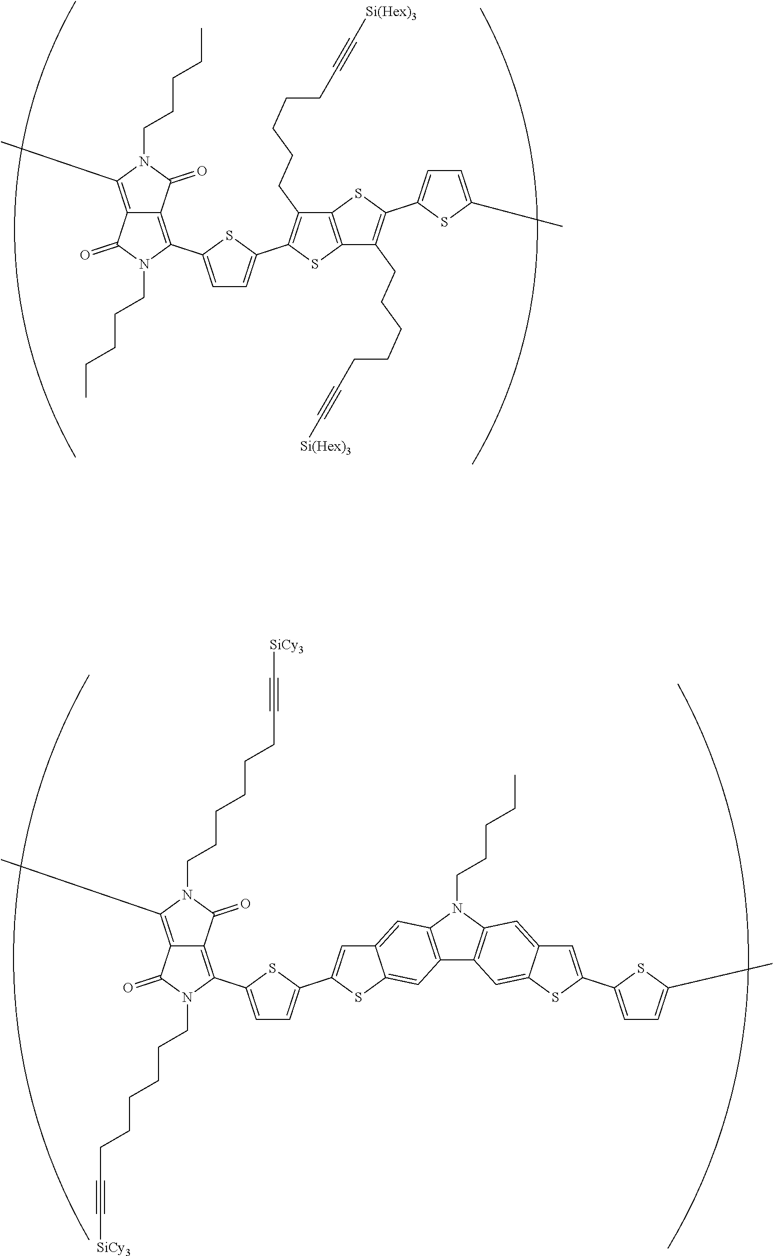

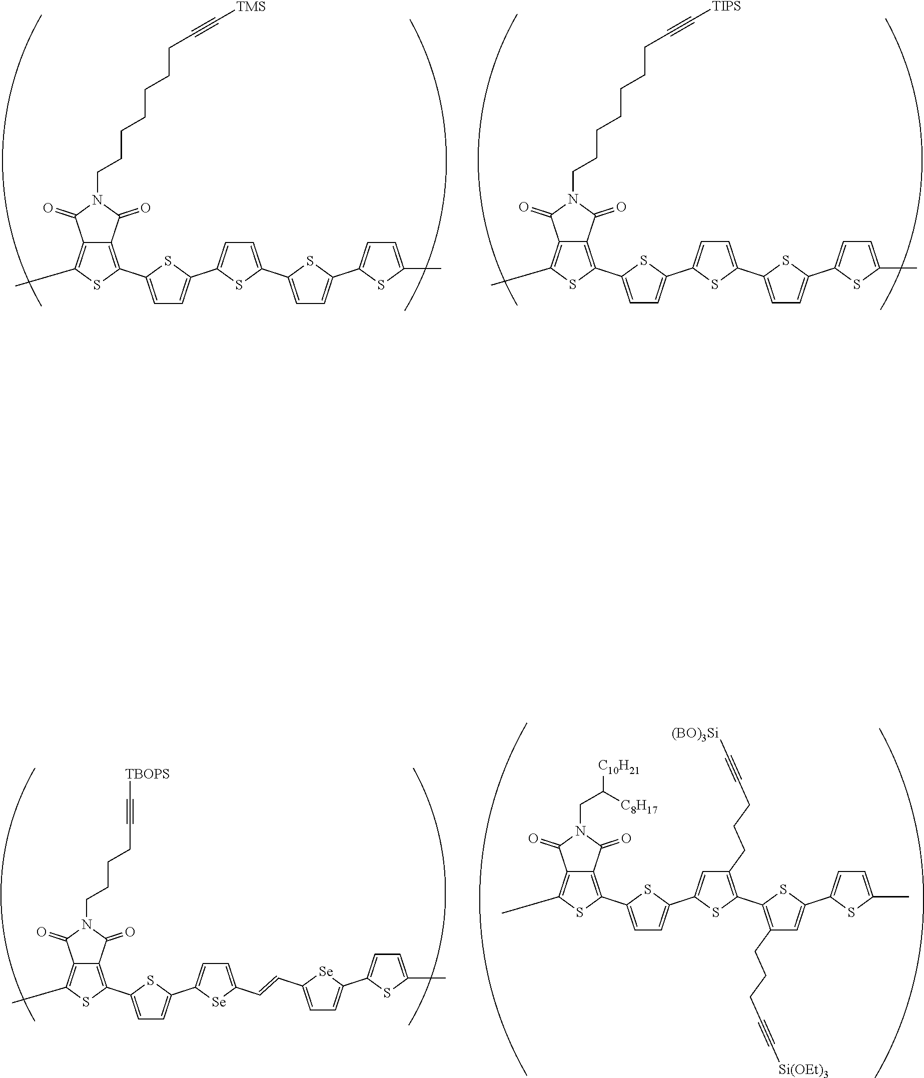

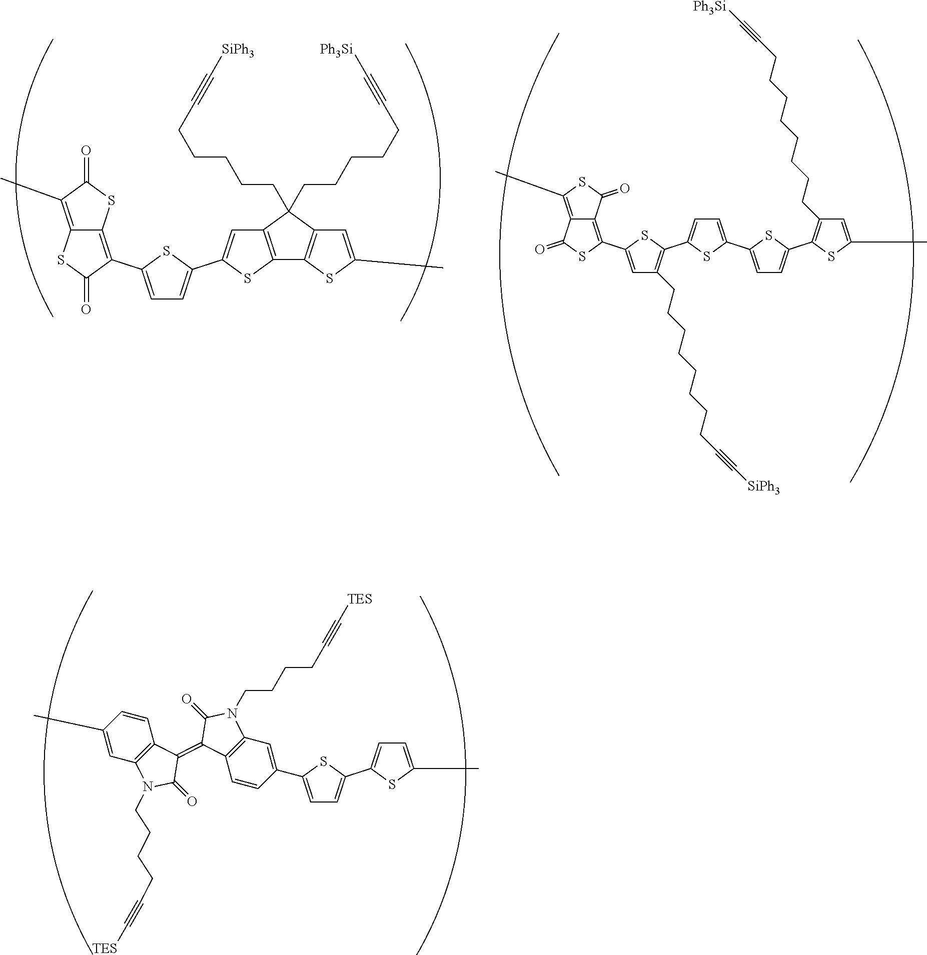

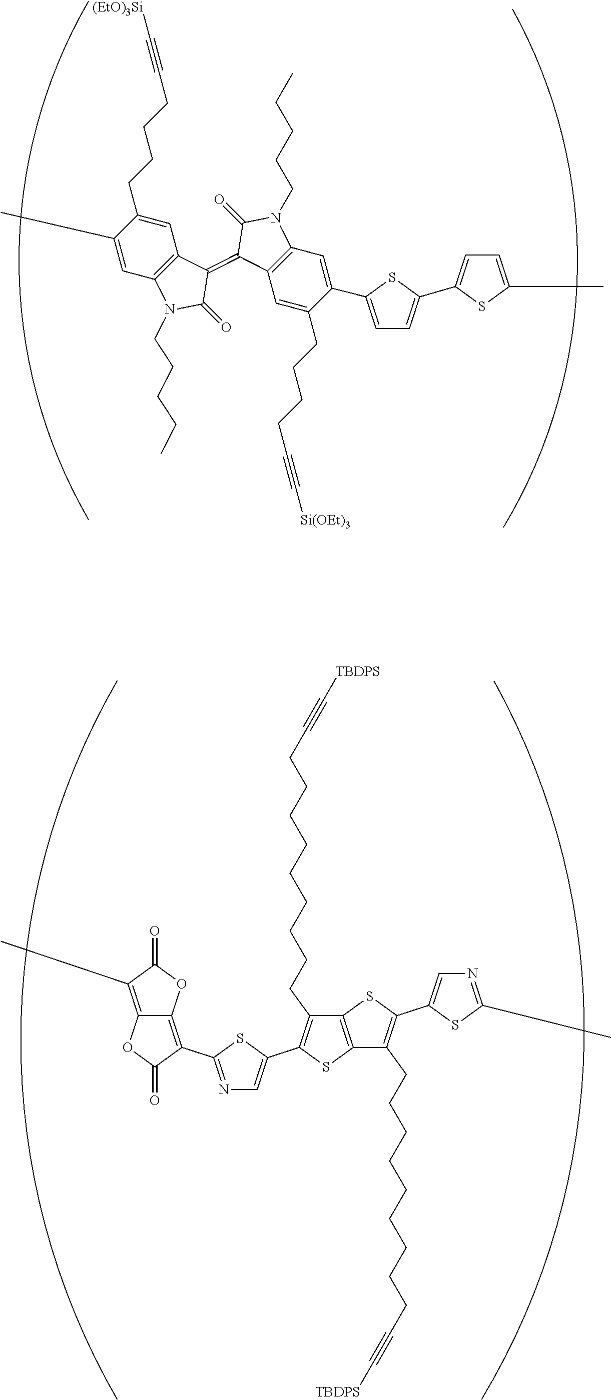

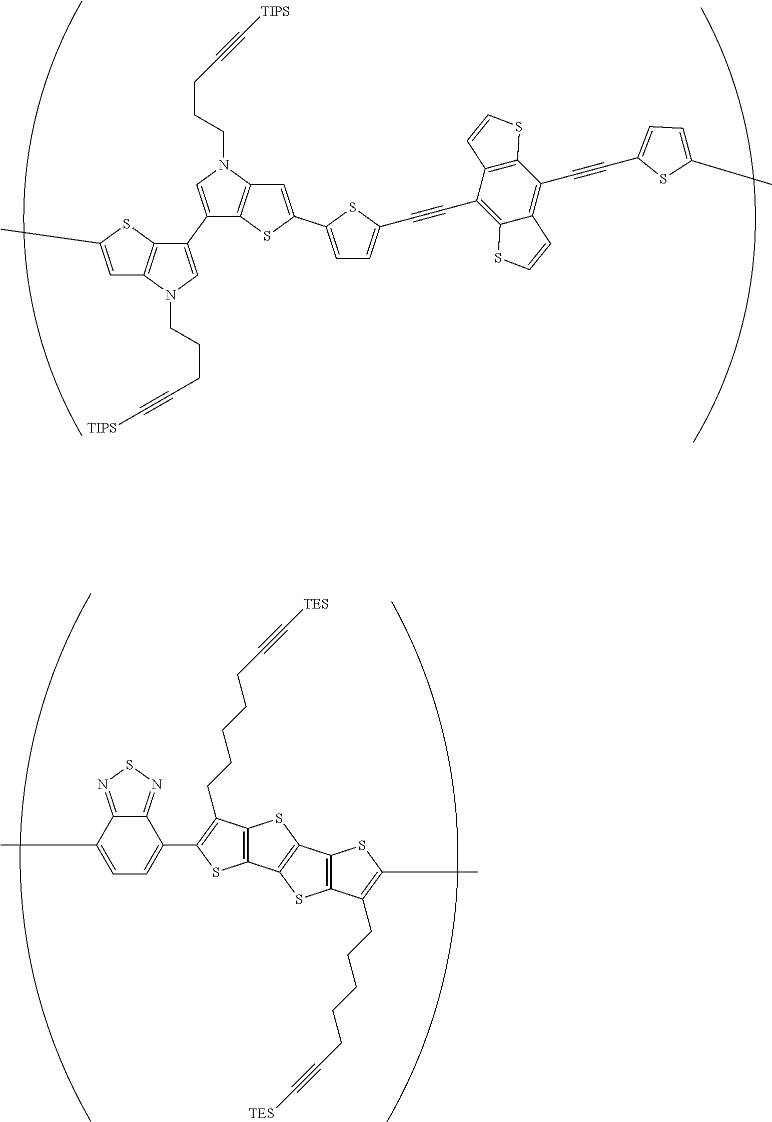

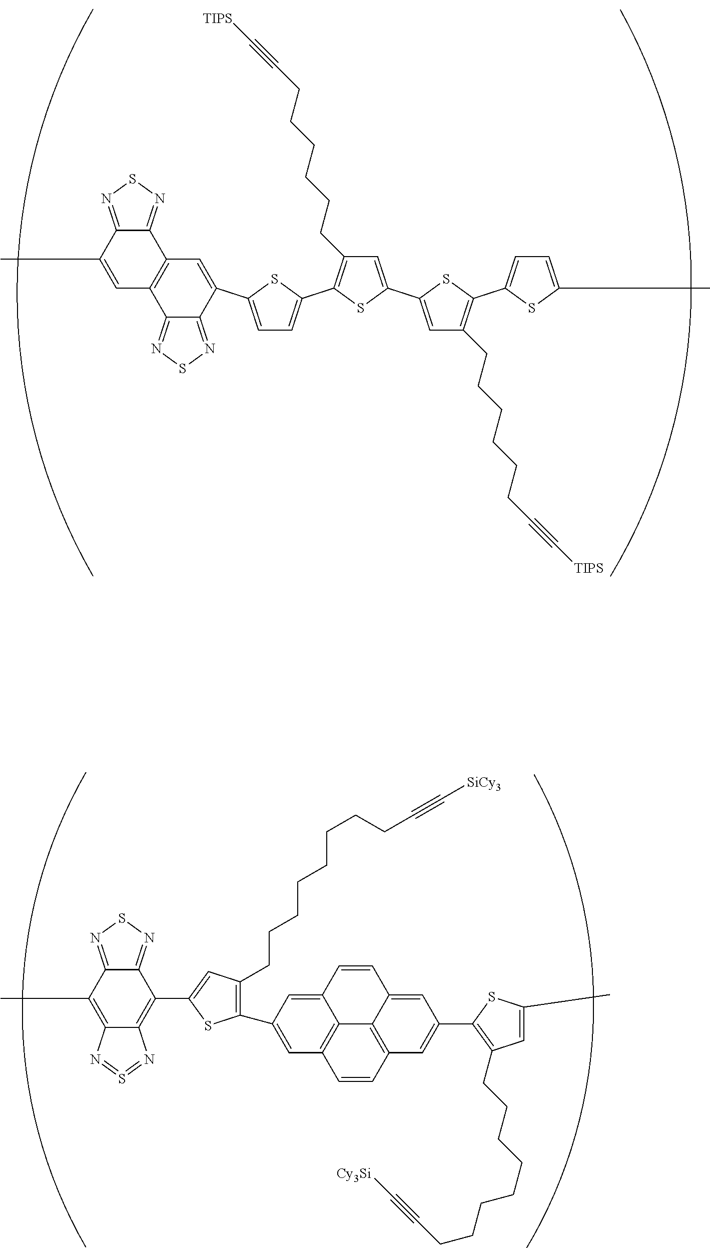

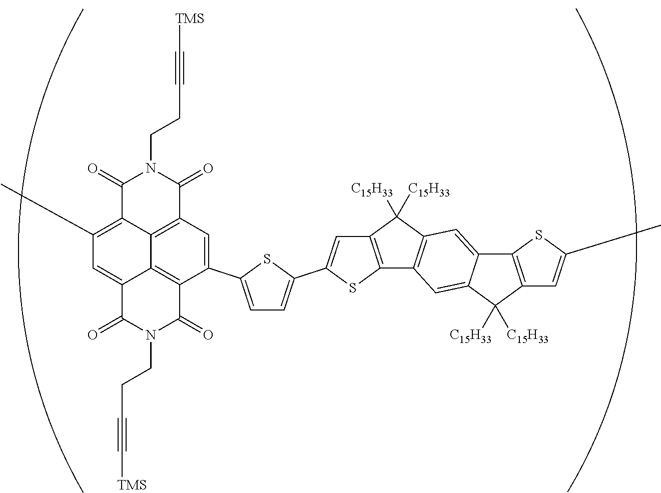

[Binder Polymer]

The organic semiconductor layer of the organic semiconductor element according to the present invention may contain the binder polymer.

The organic semiconductor element according to the present invention may be an organic semiconductor element having a layer including the organic semiconductor layer and the binder polymer.

The kinds of the binder polymer are not particularly limited, and well-known binder polymers can be used.

Examples of the binder polymer include polystyrene, poly(α-methylstyrene), polyvinyl cinnamate, poly(4-vinylphenyl), and poly(4-methylstyrene).

The weight-average molecular weight of the binder polymer is not particularly limited, but is preferably 1,000 to 2,000,000, more preferably 3,000 to 1,000,000, and still more preferably 5,000 to 600,000.

A content of the binder polymer in the organic semiconductor layer of the organic semiconductor element of the present invention is preferably 1 to 200 parts by mass, more preferably 10 to 150 parts by mass, and even more preferably 20 to 120 parts by mass with respect to 100 parts by mass of the content of the specific compound. In a case where the content is within the above range, carrier mobility and temporal stability under high temperature and high humidity of the obtained organic semiconductor are further improved.

[Other Components]

Other components may be included other than the specific compound and the binder polymer may be included in the organic semiconductor layer according to the organic semiconductor element of the present invention.

As other components, well-known additives and the like can be used.

In the organic semiconductor layer of the present invention, a content of the components other than the specific compound and the binder polymer is preferably equal to or less than 10 mass %, more preferably equal to or less than 5 mass %, even more preferably equal to or less than 1 mass %, and particularly preferably equal to or less than 0.1 mass %. In a case where the content of other components is within the above range, film formability is improved, and carrier mobility and temporal stability under high temperature and high humidity of the obtained organic semiconductor are further improved.

[Method of Forming Organic Semiconductor Layer]

The method of forming the organic semiconductor layer according to the organic semiconductor element of the present invention is not particularly limited. However, a desired organic semiconductor layer can be formed by applying the organic semiconductor composition according to the present invention described below to a predetermined base material (for example, a source electrode, a drain electrode, and a gate insulating film), and performing a drying treatment, if necessary.

The organic semiconductor element of the present invention is preferably manufactured by using the organic semiconductor composition of the present invention described below.

A method of manufacturing an organic semiconductor film or an organic semiconductor element by using the organic semiconductor composition of the present invention is not particularly limited, and known methods can be adopted. Examples thereof include a method of manufacturing an organic semiconductor film by applying the composition onto a predetermined base material and if necessary, performing a drying treatment.

The method of applying the composition onto a base material is not particularly limited, and known methods can be adopted. Examples thereof include an ink jet printing method, a screen printing method, a flexographic printing method, a bar coating method, a spin coating method, a knife coating method, a doctor blade method, and the like. An ink jet printing method, a flexographic printing method, and a screen printing method are preferable.

Preferred examples of the flexographic printing method include an aspect in which a photosensitive resin plate is used as a flexographic printing plate. By printing the composition onto a substrate according to the aspect, a pattern can be easily formed.

Among the above methods, the method of manufacturing an organic semiconductor element of the present invention preferably includes a coating step of coating a substrate with the organic semiconductor composition of the present invention described below and more preferably includes a coating step of coating a substrate with the organic semiconductor composition of the present invention and a removing step of removing the solvent from the composition with which the substrate is coated.

The organic semiconductor composition according to the present invention described below includes a solvent and preferably includes an organic solvent.

As the solvent, well-known solvents can be used.

Specific examples thereof include a hydrocarbon-based solvent such as hexane, octane, decane, toluene, xylene, mesitylene, ethylbenzene, amylbenzene, decalin, 1-methylnaphthalene, 1-ethylnaphthalene, 1,6-dimethylnaphthalene, and tetralin, a ketone-based solvent such as acetone, methyl ethyl ketone, methyl isobutyl ketone, cyclohexanone, acetophenone, propiophenone, butyrophenone, α-tetralone, and □-tetralone, a halogenated hydrocarbon-based solvent such as dichloromethane, chloroform, tetrachloromethane, dichloroethane, trichloroethane, tetrachloroethane, chlorobenzene, 1,2-dichlorobenzene, 1,2,4-trichlorobenzene, chlorotoluene, and 1-fluoronaphthalene, a heterocyclic solvent such as pyridine, picoline, quinoline, thiophene, 3-butylthiophene, and thieno[2,3-b] thiophene, a halogenated heterocyclic solvent such as 2-chlorothiophene, 3-chlorothiophene, 2,5-dichlorothiophene, 3,4-dichlorothiophene, 2-bromothiophene, 3-bromothiophene, 2,3-dibromothiophene, 2,4-dibromothiophene, 2,5-dibromothiophene, 3,4-dibromothiophene, and 3,4-dichloro-1,2,5-thiadiazole, an ester-based solvent such as ethyl acetate, butyl acetate, amyl acetate, 2-ethylhexyl acetate, γ-butyrolactone, and phenyl acetate, an alcohol-based solvent such as methanol, propanol, butanol, pentanol, hexanol, cyclohexanol, methyl cellosolve, ethyl cellosolve, and ethylene glycol, an ether solvent such as dibutyl ether, tetrahydrofuran, dioxane, anisole, ethoxybenzene, propoxybenzene, isopropoxybenzene, butoxybenzene, 2-methylanisole, 3-methylanisole, 4-methylanisole, 4-ethylanisole, dimethyl anisole (any one of 2,3-, 2,4-, 2,5-, 2,6-, 3,4-, 3,5-, and 3,6-), 1,4-benzodioxane, 2,3-dihydrobenzofuran, phthalane, chroman, and isochroman, an amide-imide-based solvent such as N,N-dimethylformamide, N,N-dimethylacetamide, 1-methyl-2-pyrrolidone, 1-methyl-2-imidazolidinone, and 1,3-dimethyl-2-imidazolidinone, a sulfoxide-based solvent such as dimethylsulfoxide, a phosphate ester-based solvent such as trimethyl phosphate, a nitrile-based solvent such as acetonitrile and benzonitrile, and a nitro-based solvent such as nitromethane and nitrobenzene.

The solvent may be used singly or a plurality of types thereof may be used in combination.

Among these, a hydrocarbon-based solvent, a ketone-based solvent, a halogenated hydrocarbon-based solvent, a heterocyclic solvent, a halogenated heterocyclic solvent, or an ether-based solvent are preferable, toluene, xylene, mesitylene, amylbenzene, tetralin, acetophenone, propiophenone, butyrophenone, α-tetralone, dichlorobenzene, anisole, ethoxybenzene, propoxybenzene, isopropoxybenzene, butoxybenzene, 2-methylanisole, 3-methylanisole, 4-methylanisole, 2,3-dihydrobenzofuran, phthalane, chroman, isochroman, 1-fluoronaphthalene, 3-chlorothiophene, and 2,5-dibromothiophene are more preferable, and toluene, xylene, tetralin, acetophenone, propiophenone, butyrophenone, α-tetralone, anisole, ethoxybenzene, propoxybenzene, butoxybenzene, 2-methylanisole, 3-methylanisole, 4-methylanisole, 2,3-dihydrobenzofuran, phthalane, chroman, isochroman, 1-fluoronaphthalene, 3-chlorothiophene, and 2,5-dibromothiophene are particularly preferable.

The boiling point of the solvent is preferably 100° C. or greater, in view of film formability. The boiling point of the solvent is more preferably 100° C. to 300° C., even more preferably 125° C. to 250° C., and particularly preferably 150° C. to 225° C.

It is preferable that a boiling point of the solvent of which the content is the greatest is 100° C. or greater and, it is more preferable that a boiling point of the total solvent is 100° C. or greater.

In a case where a solvent is contained, the content of the specific compound in the organic semiconductor composition of the present invention is preferably 0.005 to 50 mass %, more preferably 0.01 to 25 mass %, even more preferably 0.05 to 15 mass %, particularly preferably 0.05 to 3 mass %, and most preferably 0.1 to 10 mass %, with respect to the total mass of the organic semiconductor composition. In a case where the content is in the range above, the coating properties are excellent, and the organic semiconductor film can be easily formed. In the case where a binder polymer is contained, the content of the binder polymer is preferably 0.01 to 50 mass %, more preferably 0.05 to 25 mass %, and more preferably 0.1 to 10 mass % for the same reason as described above.

The drying treatment in the removing step is a treatment performed if necessary, and the optimal treatment conditions are appropriately selected according to the type of the specific compound used and the solvent. Since carrier mobility and temporal stability under high temperature and high humidity of the obtained organic semiconductor are excellent and productivity is excellent, a heating temperature is preferably 30° C. to 100° C. and more preferably 40° C. to 80° C. A heating time is preferably 10 to 300 minutes and more preferably 30 to 180 minutes for the same reason as described above.

The organic semiconductor composition according to the present invention may contain additives such as a surfactant, an antioxidant, a crystallization controlling agent, and a crystal alignment control agent, in addition to a polymer binder.

A thickness of the formed organic semiconductor layer is not particularly limited. In view of carrier mobility and temporal stability under high temperature and high humidity of the obtained organic semiconductor, the film thickness is preferably 10 to 500 rn and more preferably 30 to 200 nm.

[Configuration of Organic Semiconductor Element]

The organic semiconductor element is not particularly limited, but is preferably an organic semiconductor element having 2 to 5 terminals, and more preferably an organic semiconductor element having 2 or 3 terminals.

It is preferable that the organic semiconductor element is not a photoelectric conversion element.

The organic semiconductor element according to the present invention is preferably a non-luminous organic semiconductor element.

Examples of a 2-terminal element include a rectifier diode, a constant voltage diode, a PIN diode, a Schottky barrier diode, a surge protection diode, a diac, a varistor, a tunnel diode, and the like.

Examples of a 3-terminal element include a bipolar transistor, a Darlington transistor, a field effect transistor, an insulated gate bipolar transistor, a uni-junction transistor, a static induction transistor, a gate turn thyristor, a triac, a static induction thyristor, and the like.

Among these, a rectifier diode and transistors are preferable, and a field effect transistor is more preferable.

An organic thin film transistor (organic TFT) which is one aspect of the organic semiconductor element of the present invention is described with reference to the drawings.

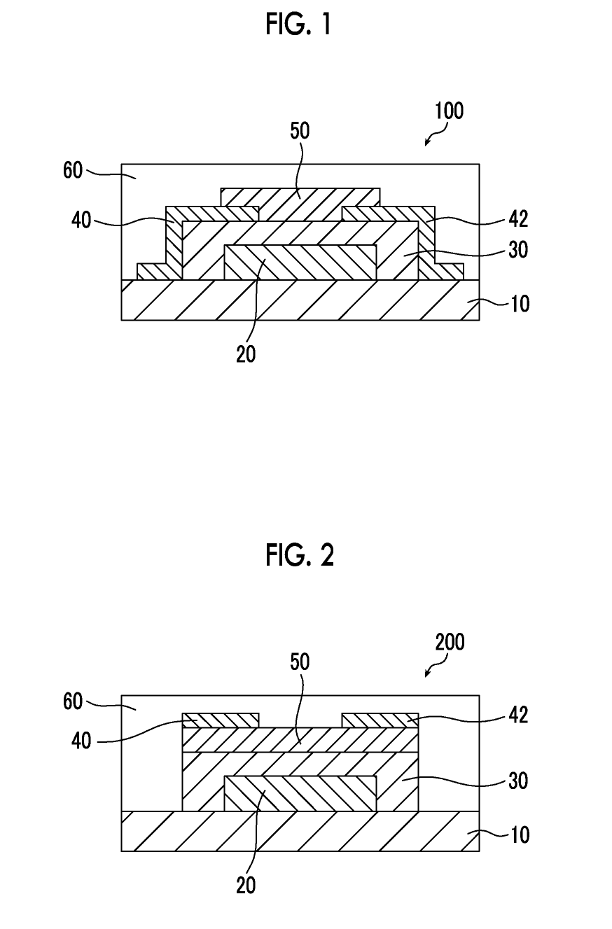

In FIG. 1, a cross-sectional view of a bottom contact type organic thin film transistor as one aspect of an organic thin film transistor (organic TFT) is schematically illustrated.

In FIG. 1, an organic thin film transistor 100 comprises a substrate 10, a gate electrode 20 disposed on the substrate 10, a gate insulating film 30 covering the gate electrode 20, a source electrode 40 and a drain electrode 42 which contact a surface of the gate insulating film 30 that is on the side opposite to the gate electrode 20 side, an organic semiconductor film 50 covering a surface of the gate insulating film 30 between the source electrode 40 and the drain electrode 42, and a sealing layer 60 covering each member. That is, the organic thin film transistor 100 is a bottom gate-bottom contact type organic thin film transistor.

In FIG. 1, the organic semiconductor film 50 corresponds to a film formed of the organic semiconductor composition according to the present invention described above.

Hereinafter, the substrate, the gate electrode, the gate insulating film, the source electrode, the drain electrode, the organic semiconductor film, the sealing layer, and a method of forming each of these will be specifically described.

<Substrate>

The substrate plays a role of supporting the gate electrode, the source electrode, the drain electrode, and the like which will be described later.

The type of the substrate is not particularly limited, and examples thereof include a plastic substrate, a glass substrate, a ceramic substrate, and the like. Among these, from the viewpoint of applicability to each device and costs, a glass substrate or a plastic substrate is preferable.

<Gate Electrode, Source Electrode, and Drain Electrode>

Examples of materials of the gate electrode, the source electrode, and the drain electrode include a metal such as gold (Au), silver, aluminum (Al), copper, chromium, nickel, cobalt, titanium, platinum, tantalum, magnesium, calcium, barium, or sodium; a conductive oxide such as InO₂, SnO₂, or indium tin oxide (ITO); a conductive polymer such as polyaniline, polypyrrole, polythiophene, polyacetylene, or polydiacetylene; a semiconductor such as silicon, germanium, or gallium arsenide; a carbon material such as fullerene, carbon nanotubes, or graphite; and the like. Among these, a metal is preferable, and silver and aluminum are more preferable.

A thickness of each of the gate electrode, the source electrode, and the drain electrode is not particularly limited, but is preferably 20 to 200 nm.

A method of forming the gate electrode, the source electrode, and the drain electrode is not particularly limited, but examples thereof include a method of vacuum vapor-depositing or sputtering an electrode material onto a substrate, a method of coating a substrate with a composition for forming an electrode, a method of printing a composition for forming an electrode onto a substrate, and the like. Furthermore, in a case where the electrode is patterned, examples of the patterning method include a photolithography method; a printing method such as ink jet printing, screen printing, offset printing, or relief printing; a mask vapor deposition method; and the like.

<Gate Insulating Film>

Examples of the material of the gate insulating film include a polymer such as polymethyl methacrylate, polystyrene, polyvinyl phenol, polyimide, polycarbonate, polyester, polyvinyl alcohol, polyvinyl acetate, polyurethane, polysulfone, polybenzoxazole, polysilsesquioxane, an epoxy resin, and a phenol resin; oxide such as silicon dioxide, aluminum oxide, and titanium oxide; and nitride such as silicon nitride. Among these materials, in view of the compatibility with the organic semiconductor film, it is preferable that the material of the gate insulating film is a polymer.

In a case where a polymer is used as the material of the gate insulating film, it is preferable that a crosslinking agent (for example, melamine) is used in combination. In a case where the crosslinking agent is used in combination, the polymer is crosslinked, and the durability of the formed gate insulating film is improved.

The film thickness of the gate insulating film is not particularly limited but is preferably 100 to 1,000 nm.

The method of forming the gate insulating film is not particularly limited, and examples thereof include a method of coating a substrate on which a gate electrode is formed with a composition for forming a gate insulating film and a method of evaporating or sputtering a material of a gate insulating film. A method of coating the composition for forming a gate insulating film is not particularly limited, and a well-known method (a bar coating method, a spin coating method, a knife coating method, a doctor blade method) can be used.

In a case where the gate insulating film is formed by applying the composition for forming a gate insulating film, heating (baking) may be performed after coating for the purpose of removing a solvent, causing crosslinking, or the like.

<Binder Polymer Layer>

The organic semiconductor element of the present invention may have the binder polymer layer between the organic semiconductor layer and the gate insulating film. In a case where the organic semiconductor element has the binder polymer layer, the organic semiconductor element preferably has the binder polymer layer between the organic semiconductor layer and the gate insulating film. A film thickness of the binder polymer layer is not particularly limited, but is preferably 20 to 500 nm. The binder polymer layer should be a layer containing the aforementioned polymer, and is preferably a layer composed of the aforementioned binder polymer.

A method of forming the binder polymer layer is not particularly limited, and a known method (a bar coating method, a spin coating method, a knife coating method, a doctor blade method, or an ink jet method) can be used.

In a case where the binder polymer layer is formed by performing coating by using a composition for forming a binder polymer layer, for the purpose of removing a solvent, causing crosslinking, or the like, the composition may be heated (baked) after coating.

<Sealing Layer>

From the viewpoint of durability, the organic semiconductor element of the present invention preferably comprises a sealing layer as an outermost layer. In the sealing layer, a known sealant can be used.

A thickness of the sealing layer is not particularly limited, but is preferably 0.2 to 10 μm.

A method of forming the sealing layer is not particularly limited, but examples thereof include a method of coating a substrate, on which the gate electrode, the gate insulating film, the source electrode, the drain electrode, and the organic semiconductor film are formed, with a composition for forming a sealing layer, and the like. Specific examples of the method of coating the substrate with the composition for forming a sealing layer are the same as the examples of the method of coating the substrate with the composition for forming a gate insulating film. In a case where the organic semiconductor film is formed by coating the substrate with the composition for forming a sealing layer, for the purpose of removing the solvent, causing crosslinking, or the like, the composition may be heated (baked) after coating.

In FIG. 2, a cross-sectional view of a top contact type organic thin film transistor as another aspect of an organic thin film transistor (organic TFT) is schematically illustrated.

In FIG. 2, an organic thin film transistor 200 comprises the substrate 10, the gate electrode 20 disposed on the substrate 10, the gate insulating film 30 covering the gate electrode 20, the organic semiconductor film 50 disposed on the gate insulating film 30, the source electrode 40 and the drain electrode 42 disposed on the organic semiconductor film 50, and the sealing layer 60 covering each member. Herein, the source electrode 40 and the drain electrode 42 are formed using the aforementioned composition of the present invention. That is, the organic thin film transistor 200 is a bottom gate-top contact type organic thin film transistor.

The substrate, the gate electrode, the gate insulating film, the source electrode, the drain electrode, the organic semiconductor film, and the sealing layer are as described above.

In FIGS. 1 and 2, the aspects of the bottom gate-bottom contact type organic thin film transistor and the bottom gate-top contact type organic thin film transistor were specifically described. However, the organic semiconductor element of the present invention can also be suitably used in a top gate-bottom contact type organic thin film transistor and a top gate-top contact type organic thin film transistor.

The organic thin film transistor described above can be suitably used for electronic paper and a display device.

[Compound]

The compound according to the present invention has the constitutional repeating unit represented by any one of Formulae (2) to (5) and has a molecular weight of 2,000 or greater. Formulae (2) to (5) have at least one monovalent group represented by Formula (1-1).

With respect to the compound according to the present invention, the compound having a repeating unit represented by any one of Formulae (2) to (5) and having a molecular weight of 2,000 or greater is the same as the compound having a repeating unit represented by any one of Formulae (2) to (5), and preferable aspects thereof are the same.

The compound of the present invention can be preferably used as the compound for an organic semiconductor (a compound for forming an organic semiconductor layer) as described above.

[Organic Semiconductor Composition]

The organic semiconductor composition according to the present invention contains the compound (aforementioned specific compound) according to the present invention and a solvent.

The organic semiconductor composition according to the present invention may contain a binder polymer.

The specific compound, the binder polymer, and the solvent in the organic semiconductor composition according to the present invention have the same meanings as the specific compound, the binder polymer, and the solvent described above, and preferable aspects thereof are also the same.

The organic semiconductor composition according to the present invention may include other components in addition to the specific compound, the binder polymer, and the solvent.

The method of manufacturing the organic semiconductor composition according to the present invention is not particularly limited, and well-known methods can be applied. For example, a desired composition can be obtained by adding a specific amount of a specific compound in the solvent and applying an appropriate stirring treatment. In a case where the binder polymer is used, the specific compound and the binder polymer are simultaneously or sequentially added, so as to suitably manufacture the composition.

[Organic Semiconductor Film]

The organic semiconductor film according to the present invention contains the specific compound.

The organic semiconductor film according to the present invention preferably contains a binder polymer.

The specific compound and the binder polymer in the organic semiconductor film according to the present invention have the same meanings as the specific compound and the binder polymer described above in the organic semiconductor element according to the present invention, and preferable aspects thereof are also the same.

The organic semiconductor film according to the present invention may include other components in addition to the specific compound and the binder polymer.

As other components, well-known additives and the like can be used.

The content of the component in addition to the specific compound and the binder polymer in the organic semiconductor film according to the present invention is preferably 10 mass % or less, more preferably 5 mass % or less, even more preferably 1 mass % or less, and particularly preferably 0.1 mass % or less. In a case where the content of other components is within the above range, film formability is improved, and carrier mobility and temporal stability under high temperature and high humidity of the obtained organic semiconductor are further improved. The solid content is an amount of the components excluding the volatilizable component such as the solvent.

The film thickness of the organic semiconductor film according to the present invention is not particularly limited. However, in view of carrier mobility and temporal stability under high temperature and high humidity of the obtained organic semiconductor, the film thickness is preferably 10 to 500 nm and more preferably 30 to 200 nm.

The organic semiconductor film according to the present invention can be suitably used in the organic semiconductor element, and can be particularly suitably used in the organic thin film transistor.

The organic semiconductor film according to the present invention can be suitably manufactured by using the organic semiconductor composition according to the present invention.

[Method of Manufacturing Organic Semiconductor Film]

The method of manufacturing the organic semiconductor film according to the present invention is not particularly limited, and well-known methods can be employed. Examples thereof include a method of manufacturing an organic semiconductor film by applying the organic semiconductor composition according to the present invention on a predetermined base material and performing a drying treatment, if necessary.

The method of applying the composition onto a base material is not particularly limited, and known methods can be adopted. Examples thereof include an ink jet printing method, a screen printing method, a flexographic printing method, a bar coating method, a spin coating method, a knife coating method, a doctor blade method, and the like. An ink jet printing method, a flexographic printing method, and a screen printing method are preferable.

Among these, the method of manufacturing the organic semiconductor film according to the present invention preferably includes a coating step of coating the substrate with the organic semiconductor composition according to the present invention and more preferably includes a coating step of coating a substrate with the organic semiconductor composition according to the present invention and a removing step of removing the solvent from the coated composition.

### EXAMPLES

Hereinafter, the present invention is specifically described with reference to examples. The materials and the amount thereof used, the proportion of the materials, the content and procedure of treatments, and the like described in the following examples can be appropriately changed within a scope that does not depart from the gist of the present invention. Therefore, the scope of the present invention is not limited to the following specific examples. Herein, unless otherwise specified, “part” and “%” are based on mass.

### Examples 1 to 14 and Comparative Examples 1 to 6

<Organic Semiconductor Compound>

Structures of Compounds 1 to 14 and Comparative Compounds 1 to 6 which were used in the organic semiconductor layer are provided below. Mw represents the weight-average molecular weight. The weight-average molecular weights of Compounds 1 to 14 and Comparative Compounds 1 to 6 were measured by the method described above.

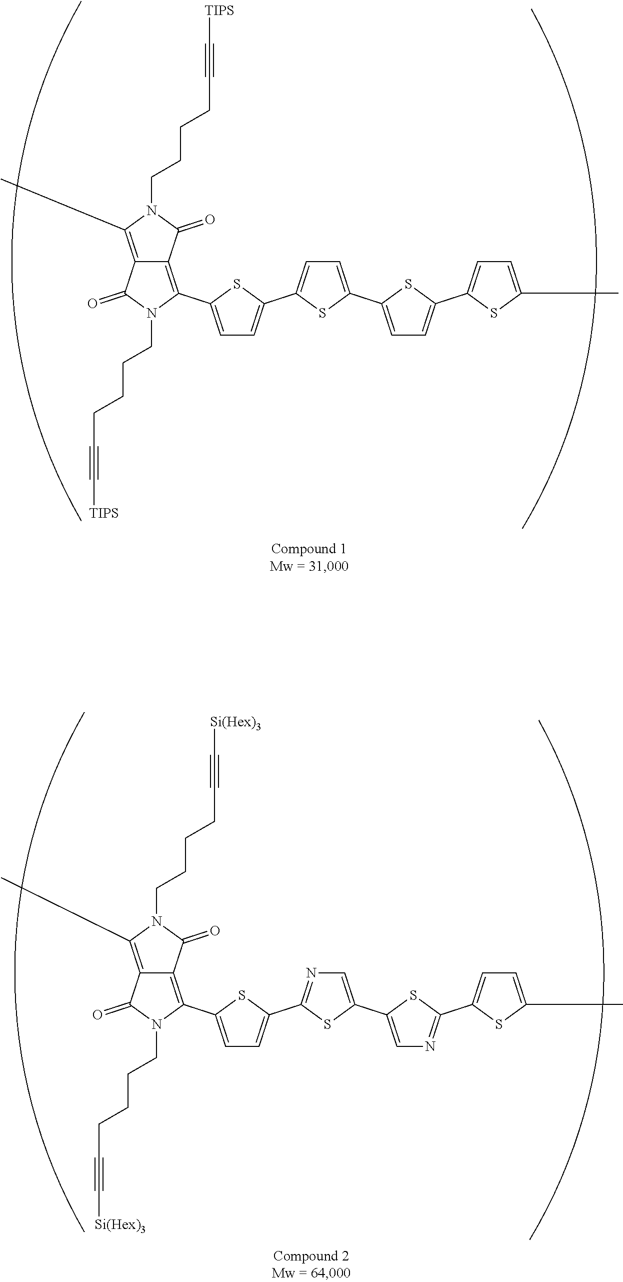

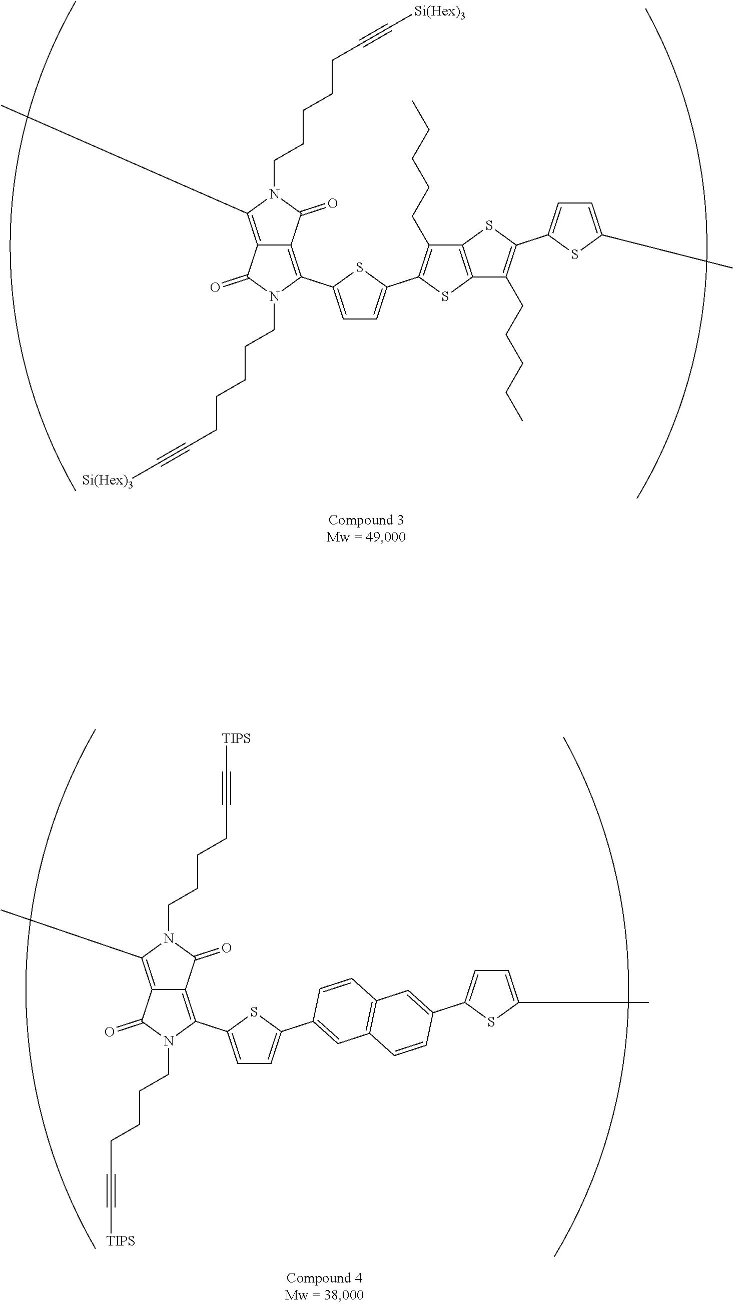

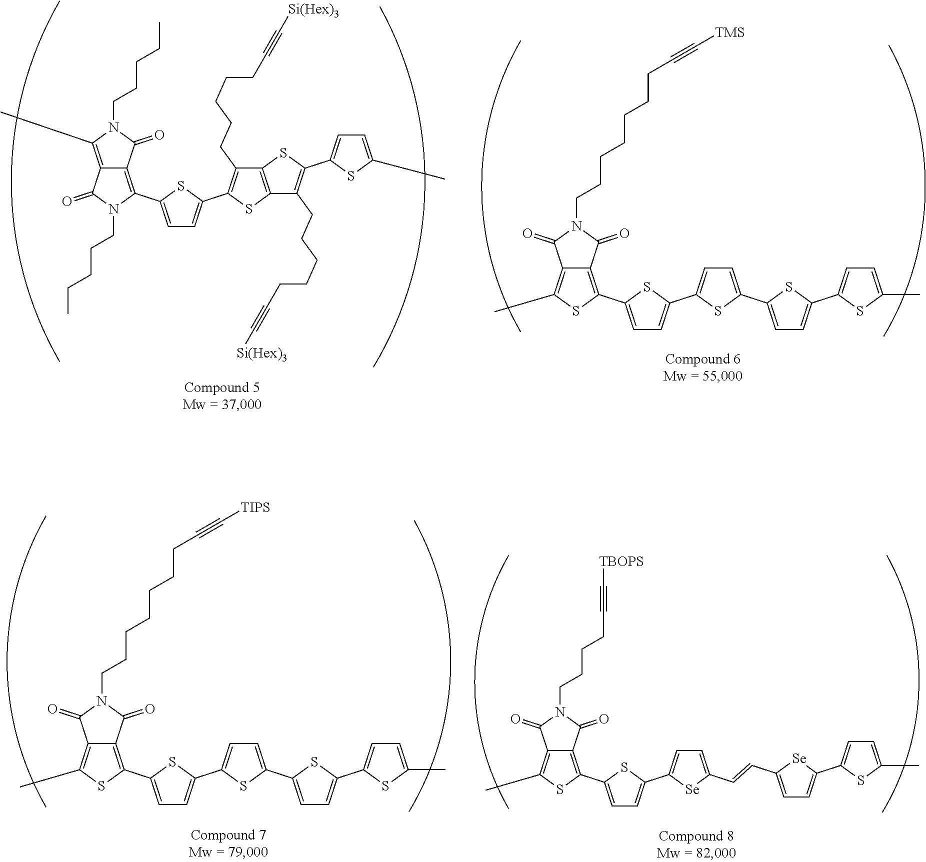

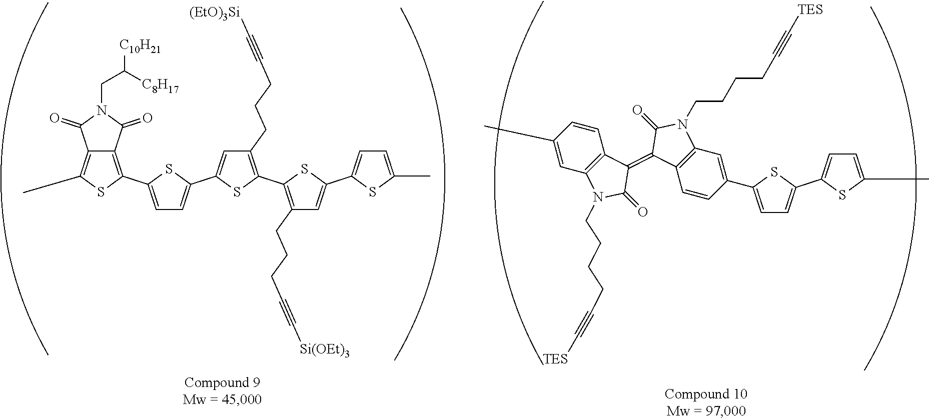

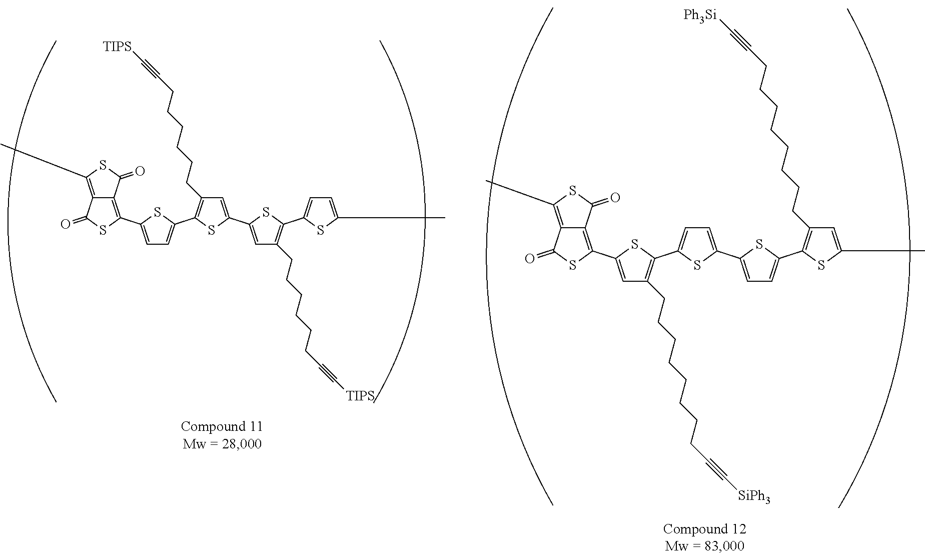

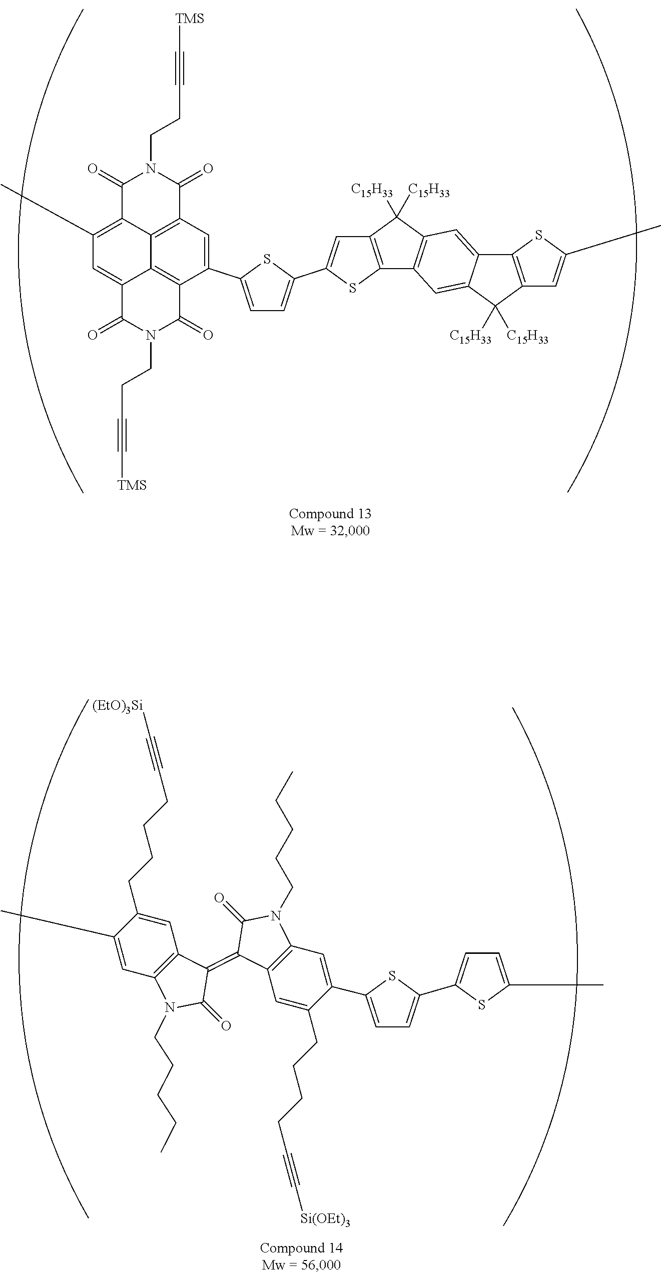

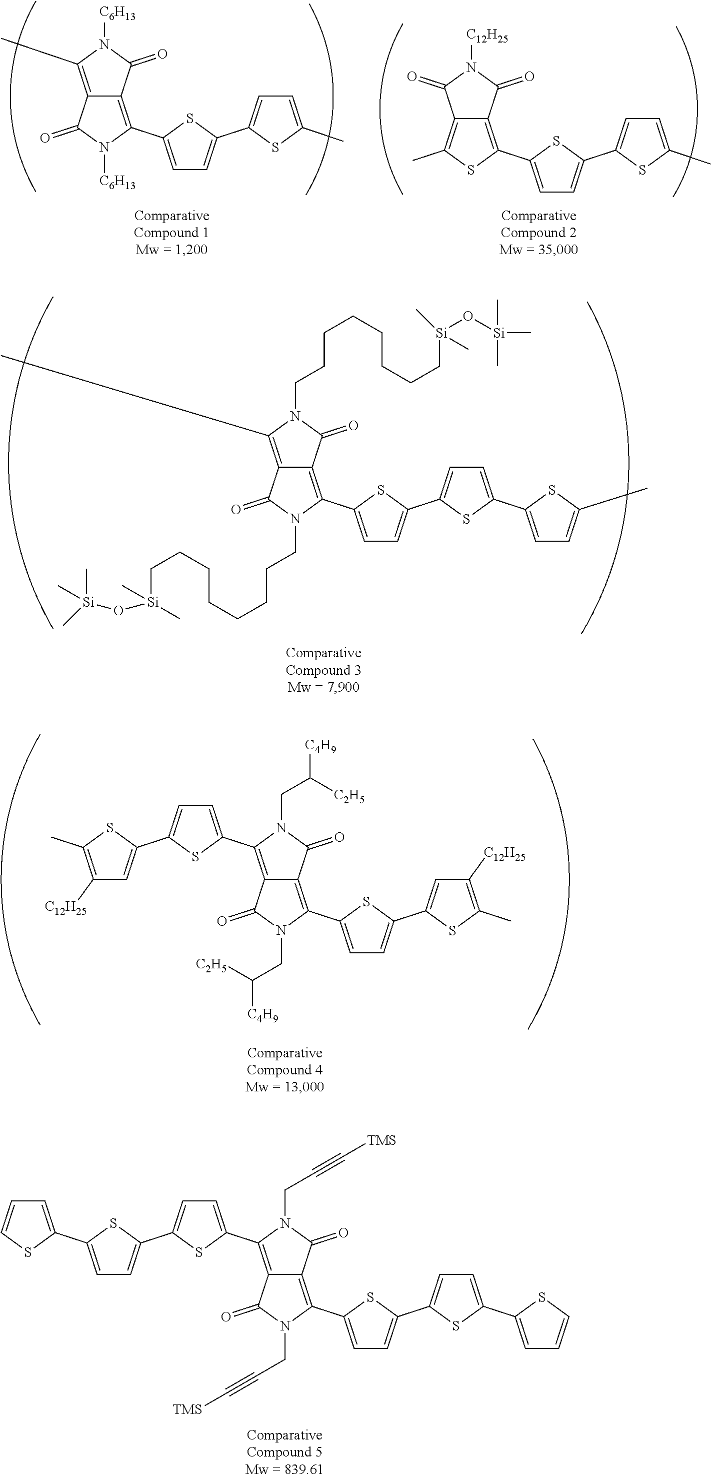

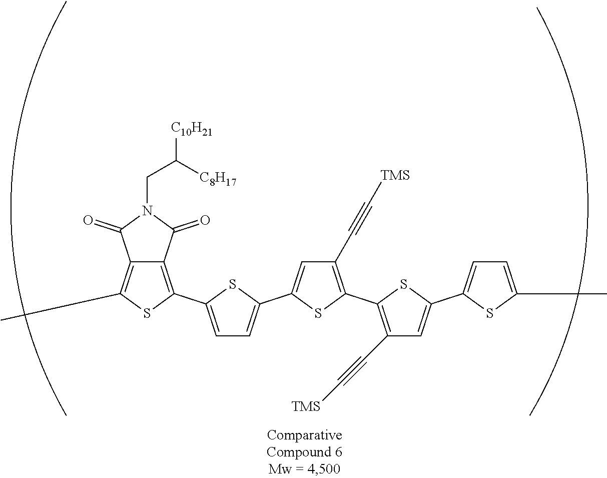

### Synthesis Example

The synthesis methods of Compounds 1 to 14 follow the method of synthesizing a general D-A-type π-conjugated polymer. As a representative example, a method of synthesizing Compounds 1 and 9 is provided.

[Synthesis of Compound 1]

Intermediate 1 which was a monomer was synthesized in a synthesis route provided in Scheme X1 with reference to Tetrahedron, 1997, 38, 6635. and Organic Electronics, 2011, 12, 993.

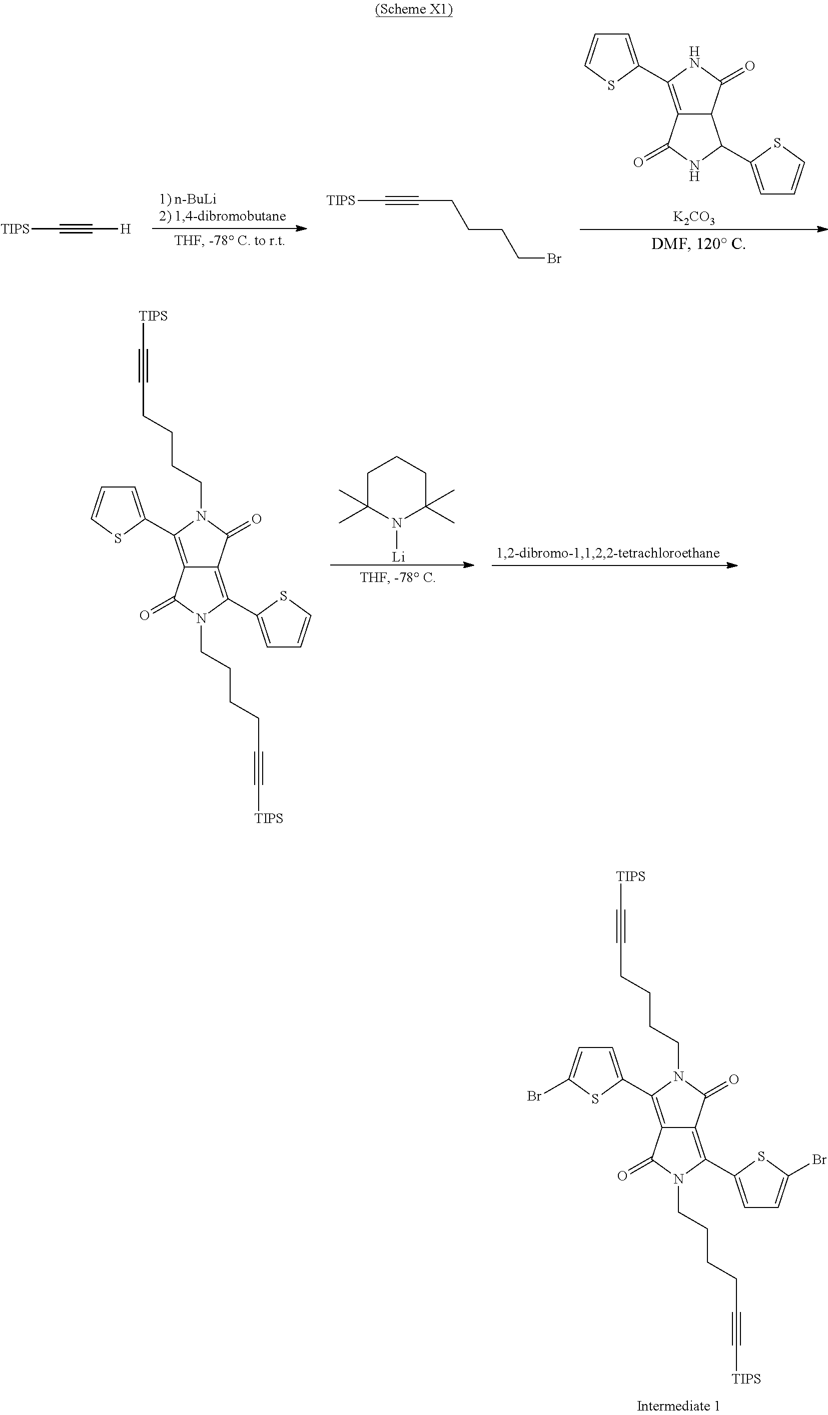

Intermediate 1 (186 mg, 0.20 mmol), 5,5′-bis(trimethylstannyl)-2,2′-bithiophene (98.4 mg, 0.20 mmol), tri(o-tolyl) phosphine (4.9 mg, 16 μmol), tri(o-tolyl)phosphine (4.9 mg, 1.6×10⁻² mmol), tris(dibenzylideneacetone)dipalladium (3.7 mg, 4.0×10⁻³ mmol), and dehydrated chlorobenzene (10 mL) were mixed and stirred at 130° C. for 24 hours under nitrogen atmosphere. Subsequently, the obtained reaction solution was cooled to room temperature. Thereafter, the cooled reaction solution was poured into a mixed solution constituting a mixture ratio of methanol (100 mL)/concentrated hydrochloric acid (5 mL) and stirring was performed for two hours. After the precipitate was filtrated and washed with methanol, soxhlet extraction was performed sequentially with methanol, acetone, and chloroform, so as to remove soluble impurities. Subsequently, soxhlet extraction was performed with chlorobenzene, the obtained solution was subjected to vacuum concentration, methanol was added, the precipitated solid content was filtrated and washed with methanol, and vacuum drying was performed at 80° C. for 12 hours, so as to obtain 130 mg of Compound 1 (yield: 77%).

The number-average molecular weight in terms of polystyrene was 8.3×10³, and the weight-average molecular weight was 3.1×10⁴.

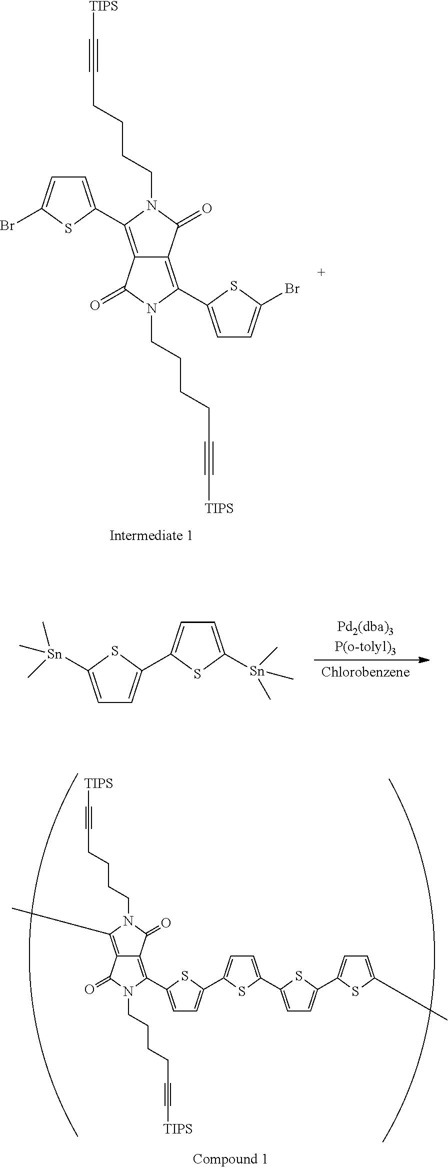

[Synthesis of Compound 9]

1,3-dibromo-5-(2-octyldodecyl)-4H-thieno[3,4-c]pyrrole-4,6 (5H), which was a monomer was synthesized according to the method described in “J. Mater. Chem., 2012, 22, 14639.”, and Intermediate 2 was synthesized by a synthetic route presented in Scheme X2.

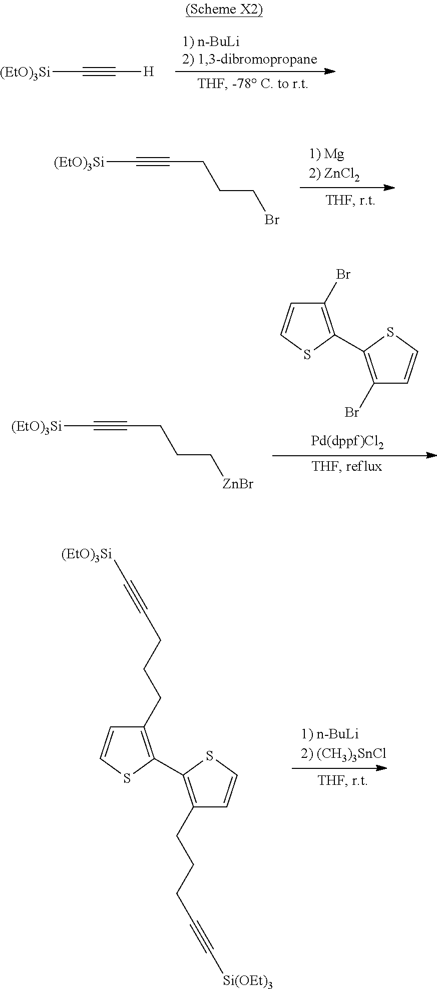

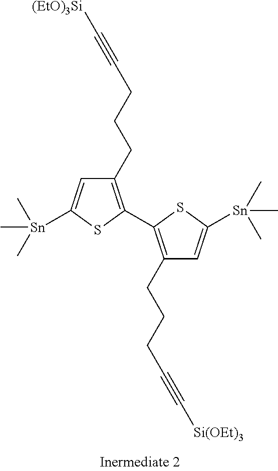

1,3-dibromo-5-(2-octyldodecyl)-4H-thieno[3,4-c]pyrrole-4,6 (5H)-dione (118 mg, 0.20 mmol), Intermediate 2 (190 mg, 0.20 mmol), tri(o-tolyl)phosphine (12.2 mg, 4.0×10⁻² mmol), tris(dibenzylideneacetone)dipalladium (9.2 mg, 1.0×10⁻² mmol), and dehydrated toluene (10 ml) were mixed, and stirring was performed under nitrogen atmosphere at 100° C. for 60 hours. Subsequently, the obtained reaction solution was cooled to room temperature. Thereafter, the cooled reaction solution was poured into a mixed solution constituting a mixture ratio of methanol (100 mL)/concentrated hydrochloric acid (10 mL) and stirring was performed for two hours. After the precipitate was filtrated and washed with methanol, soxhlet extraction was performed sequentially with methanol, acetone, and chloroform, so as to remove soluble impurities. Subsequently, soxhlet extraction was performed with dichlorobenzene, the obtained solution was subjected to vacuum concentration, methanol was added, the precipitated solid content was filtrated and washed with methanol, and vacuum drying was performed at 80° C. for 12 hours, so as to obtain 164 mg of Compound 9 (yield: 67%).

The number-average molecular weight in terms of polystyrene was 1.9×10⁴, and the weight-average molecular weight thereof was 4.5×10⁴.

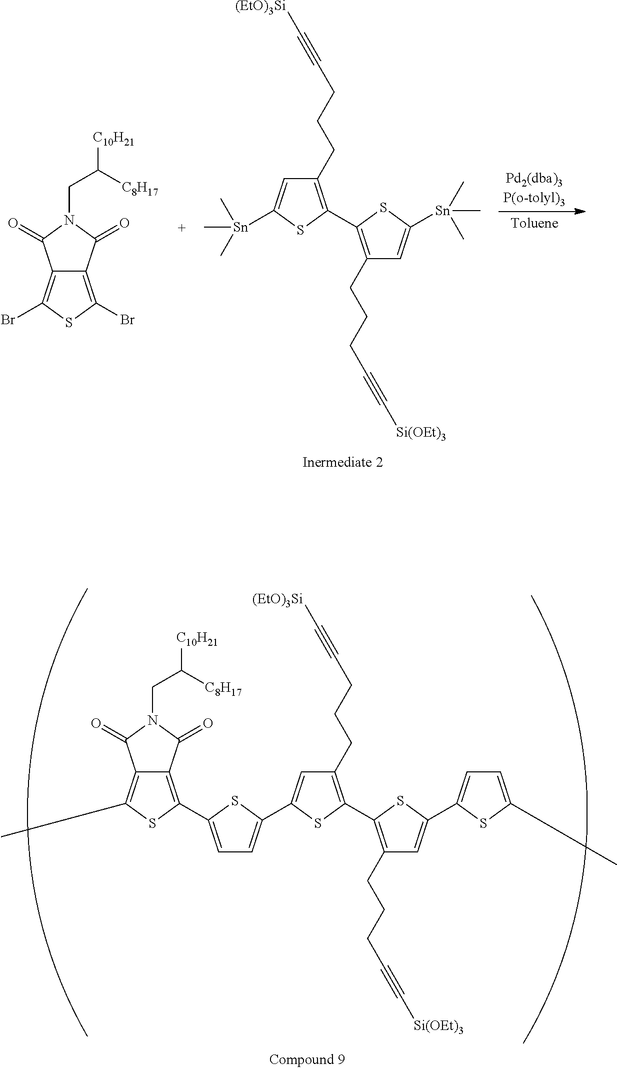

Comparative Compound 1 was a compound disclosed in JP2007-516315A, Comparative Compound 2 was a compound disclosed in JP2010-527327A, Comparative Compound 3 was a compound disclosed in WO2013/150005A (Patent Document 1), Comparative Compound 4 was a compound disclosed in JP2009-541548A, and Comparative Compound 5 was a compound disclosed in WO2013/150005A (Patent Document 1). Comparative Compound 6 was a compound obtained by directly connecting a silylethynyl group to a conjugate plane formed by a main-chain skeleton and was synthesized with reference to JP5494651B (Patent Document 2).

<Preparation of Organic Semiconductor Composition>

Compound 1 presented in Table 1 (0.20 mass %)/1,2-dichlorobenzene was weighed on a glass vial, mixing under stirring was performed for 24 hours with a mix rotor (manufactured by AS ONE Corporation), and filtration was performed with a 0.5 μm membrane filter, so as to obtain Organic Semiconductor Composition 1.

Organic Semiconductor Compositions 2 to 14 and Comparative Organic Semiconductor Compositions 1 to 6 were prepared in the same manner except for using any one of Compounds 2 to 14 or Comparative Compounds 1 to 6 instead of Compound 1.

<Preparation of Organic Thin Film Transistor (Organic TFT) Element>

Al that became a gate electrode was vapor-deposited on the glass substrate (EAGLE XG: manufactured by Coming Incorporated) (Thickness: 50 nm). Spin coating was performed with a composition for forming a gate insulating film (a propylene glycol monomethyl ether acetate (PGMEA) solution (concentration of solid content: 2 mass %) in which polyvinylphenol/melamine=1 part by mass/1 part by mass (w/w)), and the gate insulating film having a film thickness of 400 nm was formed by performing baking at 150° C. for 60 minutes. Shapes of source electrodes and drain electrodes (channel length: 40 μm, channel width: 200 μm) were drawn thereon, with silver ink (silver nano-colloid H-1, manufactured by Mitsubishi Materials Corporation) by using an ink jet device DMP-2831 (manufactured by Fujifilm Corporation). Thereafter, baking was performed in an oven at 180° C. for 30 minutes, sintering was performed, and source electrodes and drain electrodes were formed, so as to obtain an element substrate for TFT characteristic evaluation.

In a nitrogen glove box, spin coating was performed on the element substrate for TFT characteristic evaluation with Organic Semiconductor Composition 1 prepared above (for 10 seconds at 500 rpm and for 30 seconds at 1,000 rpm), and drying was performed on a hot plate at 180° C. for 10 minutes, so as to form an organic semiconductor layer such that a bottom gate bottom contact-type organic TFT element (hereinafter, also referred to as an “element”) was obtained.

Each of Elements 2 to 14 and Comparison Elements 1 to 6 were prepared in the method of manufacturing Element 1 except for using any one of Organic Semiconductor Compositions 2 to 14 or Comparative Organic Semiconductor Compositions 1 to 6 instead of Organic Semiconductor Composition 1. Elements 1 to 14 and Comparative Elements 1 to 6 obtained were organic TFT elements of Examples 1 to 14 and Comparative Examples 1 to 6.

<Characteristic Evaluation>

The characteristic evaluation was performed under the atmosphere on respective organic TFT elements (Elements 1 to 14 and Comparative Elements 1 to 6), by using a semiconductor characteristic evaluating device B2900A (manufactured by Agilent Technologies, Inc.).

(a) Carrier Mobility

Carrier mobility p was calculated by applying a voltage of −60 V between source electrodes-drain electrodes of the respective organic TFT elements (Elements 1 to 14 and Comparative Elements 1 to 6), changing a gate voltage in the range of +10 V to −60 V, and using an equation below indicating a drain current Id, so as to evaluate the following seven steps.

I_{d}=(w/2L)μCᵢ(V_{g}−Vₜₕ)²

In the equation, L represents a gate length, w represents a gate width, Cᵢ represents the capacitance per unit area of the insulating layer, V_{g} represents a gate voltage, and Vₜₕ represents a threshold voltage.

The obtained results are shown in the following table.

“S”: 0.25 cm²/Vs or greater and less than 0.30 cm²/Vs

“AA”: 0.2 cm²/Vs or greater and less than 0.25 cm²/Vs

“A”: 0.1 cm²/Vs or greater and less than 0.2 cm²/Vs

“B”: 0.05 cm²/Vs or greater and less than 0.1 cm²/Vs

“C”: 0.02 cm²/Vs or greater and less than 0.05 cm²/Vs

“D”: 10⁻⁴ cm²/Vs or greater and less than 0.02 cm²/Vs

“E”: 10⁻⁵ cm²/Vs or less

As the carrier mobility g is higher, the carrier mobility it is more preferable. In practice, it is required to be “C” or greater, preferably “B” or greater, and more preferably “A” or greater.

(b) Temporal Stability Under High Temperature and High Humidity

After the respective organic TFT elements (Elements 1 to 14 and Comparative Elements 1 to 6) were stored under the conditions at 60° C. in the humidity of 80% or less for 24 hours, carrier mobility maintenance ratio (in the following equation) in a case where carrier mobility was measured in the same method as “(a) Carrier mobility” was evaluated in the following five levels, so as to obtain an index of temporal stability under high temperature and high humidity. As this value is greater, temporal stability under high temperature and high humidity becomes higher. In practice, “B” or greater is preferable, and “A” or greater is more preferable.

Carrier mobility maintenance ratio (%) after storage under high temperature and high humidity=Carrier mobility (after storage under high temperature and high humidity)/carrier mobility (before storage under high temperature and high humidity)×100

“A”: 90% or greater

“B”: 75% or greater and less than 90%

“C”: 50% or greater and less than 75%

“D”: 25% or greater and less than 50%

“E”: Less than 25%

In the section “whether to correspond to Formulae (2) to (5)” in the table below, A means “to correspond” and B means “not to correspond”.

TABLE 1

| | | | | | | | | Evaluation | |
|---|---|---|---|---|---|---|---|---|---|
| | | Organic semiconductor compound | | | | | | | Temporal stability |
| | | | | | | | Whether to | | under high |
| | | | | | | | correspond | Carrier | temperature and |
| | Organic TFT | | Formula (1-1) | | | Kind of | Formulae | mobility | high humidity |
| Table 1 | element | Kind | R¹, R², R³ | n | Position | acceptor | (2) to (5) | (cm²/Vs) | (%) |
| Example 1 | Element 1 | Compound 1 | Isopropyl group | 4 | A | A-3 | A | AA | A |
| Example 2 | Element 2 | Compound 2 | Hexyl group | 4 | A | A-3 | A | S | A |
| Example 3 | Element 3 | Compound 3 | Hexyl group | 5 | A | A-3 | A | AA | A |
| Example 4 | Element 4 | Compound 4 | Isopropyl group | 4 | A | A-3 | A | B | A |
| Example 5 | Element 5 | Compound 5 | Hexyl group | 5 | D | A-3 | A | A | A |
| Example 6 | Element 6 | Compound 6 | Methyl group | 7 | A | A-1 | A | B | A |
| Example 7 | Element 7 | Compound 7 | Isopropyl group | 7 | A | A-1 | A | A | A |
| Example 8 | Element 8 | Compound 8 | Butyl group, | 4 | A | A-1 | A | A | A |
| | | | Phenyl group | | | | | | |
| Example 9 | Element 9 | Compound 9 | Ethoxy group | 3 | D | A-1 | A | B | A |
| Example 10 | Element 10 | Compound 10 | Ethyl group | 4 | A | A-5 | A | B | A |
| Example 11 | Element 11 | Compound 11 | Isopropyl group | 6 | D | A-12 | B | C | B |
| Example 12 | Element 12 | Compound 12 | Phenyl group | 8 | D | A-3 | A | C | A |
| Example 13 | Element 13 | Compound 13 | Methyl group | 2 | A | A-10 | B | C | B |
| Example 14 | Element 14 | Compound 14 | Ethoxy group | 4 | A | A-5 | A | C | A |
| Comparative | Comparative | Comparative | — | — | — | A-3 | — | E | E |
| Example 1 | Element 1 | Compound 1 | | | | | | | |
| Comparative | Comparative | Comparative | — | — | — | A-1 | — | D | D |
| Example 2 | Element 2 | Compound 2 | | | | | | | |
| Comparative | Comparative | Comparative | — | — | — | A-3 | — | C | C |
| Example 3 | Element 3 | Compound 3 | | | | | | | |
| Comparative | Comparative | Comparative | — | — | — | A-3 | — | D | C |
| Example 4 | Element 4 | Compound 4 | | | | | | | |
| Comparative | Comparative | Comparative | — | — | — | A-3 | — | C | D |
| Example 5 | Element 5 | Compound 5 | | | | | | | |
| Comparative | Comparative | Comparative | — | — | — | A-1 | — | E | E |
| Example 6 | Element 6 | Compound 6 | | | | | | | |

From the results presented in Table 1, the following can be known.

It was found that the organic TFT elements of Examples 1 to 14 have excellent carrier mobility and excellent temporal stability under high temperature and high humidity. In particular, it is understood that, in a case where a compound having a structure corresponding to Formulae (2) to (5) is used, carrier mobility was excellent and temporal stability under high temperature and high humidity was excellent.

In a case where Example 6 is compared with Example 7, it is clearly understood that, as the number of carbon atoms in each of the substituents (R¹, R², and R³) of Si at the silylethynyl group terminal becomes greater (the number of carbon atoms is preferably 2 or greater and more preferably 3 or greater), in other words, as the steric hindrance becomes greater, the carrier mobility is improved.

In a case where Example 3 is compared with Example 5, it is clearly understood that the carrier mobility is further improved by introducing an alkyl group having a silylethynyl group terminal represented by Formula (1-1) to an acceptor side in the main-chain skeleton of Formula (1).

On the other hand, as clearly understood from Comparative Examples 1, 2 and 4, in a case where an alkyl group having no silylethynyl group terminal is introduced as a substituent, in any one of the carrier mobility and the temporal stability under high temperature and high humidity, a desired effect was not exhibited.

As shown in Comparative Example 3, in a case where an alkyl group in which the silyl terminal was directly linked without using an ethynyl group was introduced, the effect of temporal stability under high temperature and high humidity was not exhibited.

As presented in Comparative Example 5, in the case of a methyl group having a silylethynyl group terminal (corresponding to a case where n in Formula (1-1) was 1), the effect of temporal stability under high temperature and high humidity was not exhibited.

As shown in Comparative Example 6, in a case where a silylethynyl group is directly connected to the conjugate plane of the main-chain skeleton (corresponding to the case where n in Formula (1-1) is 0), in any one of the carrier mobility and the temporal stability under high temperature and high humidity, a desired effect was not exhibited.

### EXPLANATION OF REFERENCES

10: substrate
20: gate electrode
30: gate insulating film
40: source electrode
42: drain electrode
50: organic semiconductor film
60: sealing layer
100, 200: organic thin film transistor

What is claimed is:

1. An organic semiconductor element comprising:
an organic semiconductor layer containing a compound having a molecular weight of 2,000 or greater and a repeating unit represented by Formula (1),
D-A (1)
in Formula (1), A represents an electron acceptor unit including a partial structure having at least one of a sp2 nitrogen atom, a carbonyl group, or a thiocarbonyl group in a ring structure, D represents an electron donor unit including a divalent aromatic heterocyclic group having at least one of a N atom, an O atom, a S atom, or a Se atom in a ring structure or a divalent aromatic hydrocarbon group consisting of a fused ring structure having two or more rings as a partial structure, and D and/or A has at least one monovalent group represented by Formula 1-1, 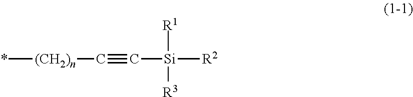
in Formula (1-1), n is an integer of 2 to 30, and R¹, R², and R³ each independently represent an alkyl group, an alkoxy group, an aryl group, or a heteroaryl group which may have a substituent, and * represents a bonding site to another structure.

2. The organic semiconductor element according to claim 1,
wherein, in Formula (1), A has at least one structure selected from the group consisting of structures represented by Formulae (A-1) to (A-12), as a partial structure, 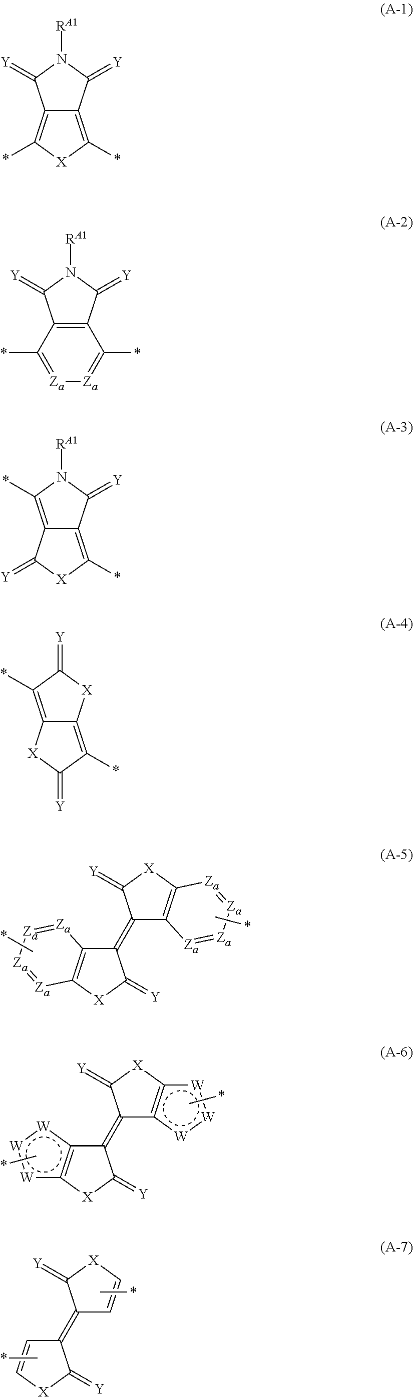 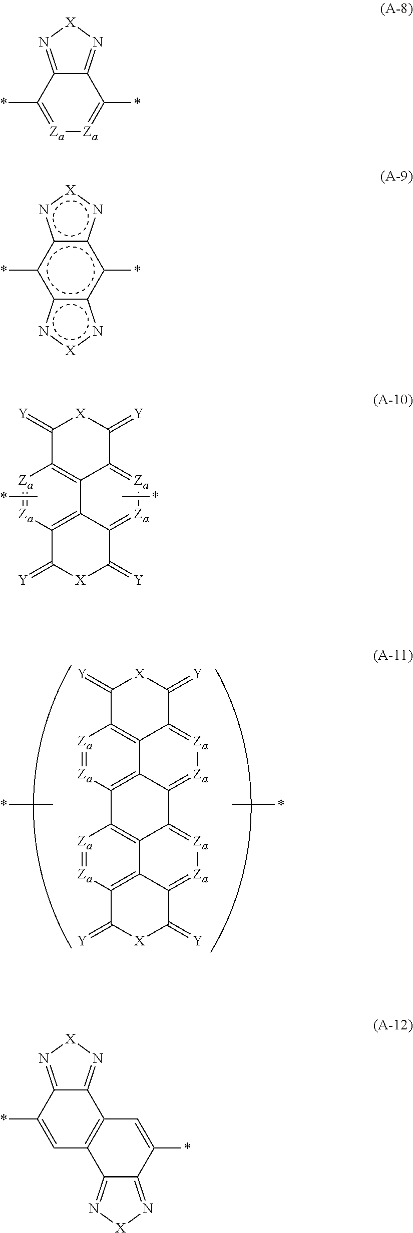
in Formulae (A-1) to (A-12), X's each independently represent an O atom, a S atom, a Se atom, or NR^{A1}, Y's each independently represent an O atom or a S atom, Zₐ's each independently represent CR^{A2} Or a N atom, W's each independently represent C(R^{A2})₂, NR^{A1}, a N atom, CR^{A2}, an O atom, a S atom, or a Se atom, R^{A1}'s each independently represent an alkyl group that may contain at least one of —O—, —S—, or —NR^{A3}—, a monovalent group represented by Formula (1-1), or a bonding site to another structure, R^{A2}'s each independently represent an alkyl group that may contain at least one of —O—, —S—, or —NR^{A3}—, a hydrogen atom, a halogen atom, a monovalent group represented by Formula (1-1), or a bonding site to another structure, *'s each independently represent a bonding site to another structure, and R^{A3} represents a hydrogen atom or a substituent.

3. The organic semiconductor element according to claim 1,
wherein, in Formula (1), D represents a structure represented by Formula (D-1), 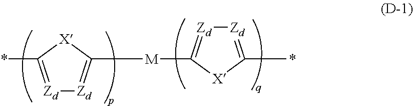
in Formula (D-1), X″s each independently represent an O atom, a S atom, a Se atom, or NR^{D1}, Z_{d}'s each independently represent an N atom or CR^{D2}, R^{D1}'s each independently represent a monovalent organic group that may be a monovalent group represented by Formula (1-1), R^{D2}'s each independently represent a hydrogen atom or a monovalent organic group that may be a monovalent group represented by Formula (1-1), M represents a single bond, a divalent aromatic heterocyclic group, a divalent aromatic hydrocarbon group, an alkenylene group, an alkynylene group, or a divalent group obtained by combining these, p and q each independently represent an integer of 0 to 4, and *'s each independently represent a bonding site to another structure, and M represents an alkyl group that may contain at least one of —O—, —S—, or —NR^{D3}— as a substituent or a monovalent group represented by Formula (1-1), and R^{D3} represents a hydrogen atom or a substituent.

4. The organic semiconductor element according to claim 1,
wherein the repeating unit represented by Formula (1) is a repeating unit represented by any one of Formulae (2) to (5), 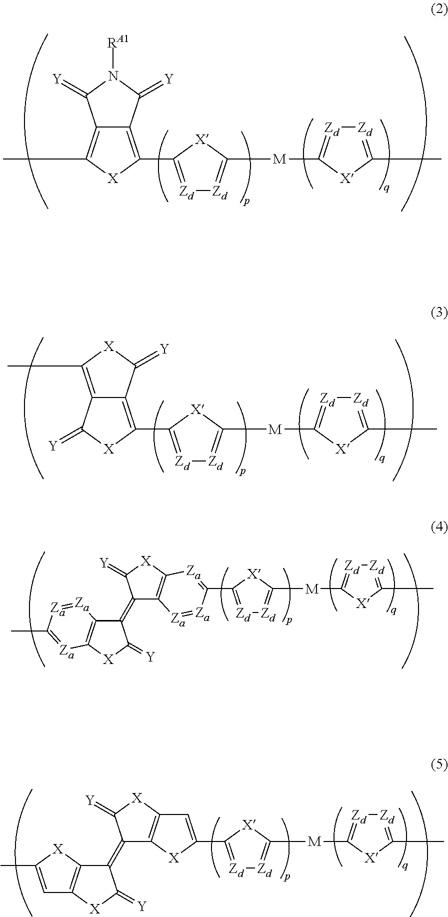
in Formulae (2) to (5), X's each independently represent an O atom, a S atom, a Se atom, or NR^{A1}, Y's each independently represent an O atom or a S atom, Zₐ's each independently represent CR^{A2} or a N atom, R^{A1}'s each independently represent an alkyl group that may contain at least one of —O—, —S—, or —NR^{A3}—, a monovalent group represented by Formula (1-1), or a bonding site to another structure, R^{A2}'s each independently represent an alkyl group that may contain at least one of —O—, —S—, or —NR^{A3}—, a hydrogen atom, a halogen atom, a monovalent group represented by Formula (1-1), or a bonding site to another structure, R^{A3} represents a hydrogen atom or a substituent, X″s each independently represent an O atom, a S atom, a Se atom, or NR^{D1}, Z_{d}'s each independently represent an N atom or CR^{D2}, R^{D1}'s each independently represent a monovalent organic group that may be a monovalent group represented by Formula (1-1), R^{D2}'s each independently represent a hydrogen atom or a monovalent organic group that may be a monovalent group represented by Formula (1-1), M represents a single bond, a divalent aromatic heterocyclic group, a divalent aromatic hydrocarbon group, an alkenylene group, an alkynylene group, or a divalent group obtained by combining these, and p and q each independently represent an integer of 0 to 4, and M represents an alkyl group that may contain at least one of —O—, —S—, or —NR^{D3}— as a substituent or a monovalent group represented by Formula (1-1), and R^{D3} represents a hydrogen atom or a substituent.

5. The organic semiconductor element according to claim 2,
wherein Formulae (A-1) to (A-12) has at least one of R^{A1} or R^{A2}, and at least one of R^{A1} or R^{A2} in each of the formulae is a monovalent group represented by Formula (1-1).

6. The organic semiconductor element according to claim 4,
wherein Formulae (2) to (5) has at least one of R^{A1} or R^{A2}, and at least one of R^{A1} or R^{A2} in each of the formulae is a monovalent group represented by Formula (1-1).

7. The organic semiconductor element according to claim 1,
wherein in Formula (1-1), the number of carbon atoms included in each of R¹, R², and R³ is 2 or greater.

8. A compound having a molecular weight of 2,000 or greater and having a repeating unit represented by any one of Formulae (2) to (5), wherein, Formulae (2) to (5) have at least one monovalent group represented by Formula (1-1), 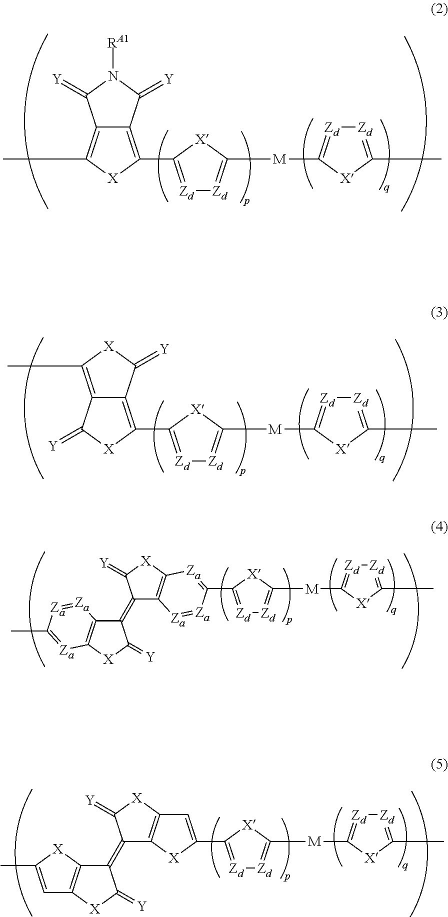
in Formulae (2) to (5), X's each independently represent an O atom, a S atom, a Se atom, or NR^{A1}, Y's each independently represent an O atom or a S atom, Zₐ's each independently represent CR^{A2} or a N atom, R^{A1}'s each independently represent an alkyl group that may contain at least one of —O—, —S—, or —NR^{A3}—, a monovalent group represented by Formula (1-1), or a bonding site to another structure, R^{A2}'s each independently represent an alkyl group that may contain at least one of —O—, —S—, or —NR^{A3}—, a hydrogen atom, a halogen atom, a monovalent group represented by Formula (1-1), or a bonding site to another structure, R^{A3} represents a hydrogen atom or a substituent, X″s each independently represent an O atom, a S atom, a Se atom, or NR^{D1}, Z_{d}'s each independently represent an N atom or CR^{D2}, R^{D1}'s each independently represent a monovalent organic group that may be a monovalent group represented by Formula (1-1), R^{D2}'s each independently represent a hydrogen atom or a monovalent organic group that may be a monovalent group represented by Formula (1-1), M represents a single bond, a divalent aromatic heterocyclic group, a divalent aromatic hydrocarbon group, an alkenylene group, an alkynylene group, or a divalent group obtained by combining these, and p and q each independently represent an integer of 0 to 4, and M represents an alkyl group that may contain at least one of —O—, —S—, or —NR^{D3}— as a substituent or a monovalent group represented by Formula (1-1), and R^{D3} represents a hydrogen atom or a substituent, 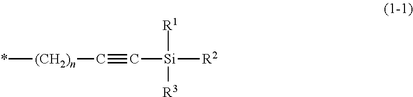
in Formula (1-1), n is an integer of 2 to 30, and R¹, R², and R³ each independently represent an alkyl group, an alkoxy group, an aryl group, or a heteroaryl group which may have a substituent, and * represents a bonding site to another structure.

9. An organic semiconductor composition comprising:
a compound having a molecular weight of 2,000 or greater and including a repeating unit represented by Formula (1); and a solvent,
D-A (1)
in Formula (1), A represents an electron acceptor unit including a partial structure having at least one of a sp2 nitrogen atom, a carbonyl group, or a thiocarbonyl group in a ring structure, D represents an electron donor unit including a divalent aromatic heterocyclic group having at least one of a N atom, an O atom, a S atom, or a Se atom in a ring structure or a divalent aromatic hydrocarbon group consisting of a fused ring structure having two or more rings as a partial structure, and D and/or A has at least one monovalent group represented by Formula (1-1), 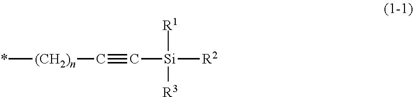
in Formula (1-1), n is an integer of 2 to 30, and R¹, R² and R³ each independently represent an alkyl group, an alkoxy group, an aryl group, or a heteroaryl group which may have a substituent, and * represents a bonding site to another structure.

10. An organic semiconductor film comprising:
a compound having a molecular weight of 2,000 or greater and having a repeating unit represented by Formula (1),
D-A (1)
in Formula (1), A represents an electron acceptor unit including a partial structure having at least one of a sp2 nitrogen atom, a carbonyl group, or a thiocarbonyl group in a ring structure, D represents an electron donor unit including a divalent aromatic heterocyclic group having at least one of a N atom, an O atom, a S atom, or a Se atom in a ring structure or a divalent aromatic hydrocarbon group consisting of a fused ring structure having two or more rings as a partial structure, and D and/or A has at least one monovalent group represented by Formula (1-1), 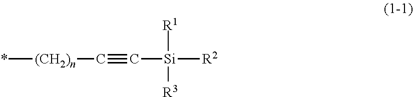
in Formula (1-1), n is an integer of 2 to 30, and R¹, R², and R³ each independently represent an alkyl group, an alkoxy group, an aryl group, or a heteroaryl group which may have a substituent, and * represents a bonding site to another structure.

11. A method of manufacturing an organic semiconductor film, comprising: a coating step of coating a substrate with the organic semiconductor composition according to claim 9.

12. The organic semiconductor element according to claim 2,
wherein, in Formula (1), D represents a structure represented by Formula (D-1), 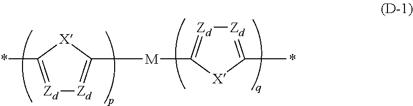
in Formula (D-1), X″s each independently represent an O atom, a S atom, a Se atom, or NR^{D1}, Z_{d}'s each independently represent an N atom or CR^{D2}, R^{D1}'s each independently represent a monovalent organic group that may be a monovalent group represented by Formula (1-1), R^{D2}'s each independently represent a hydrogen atom or a monovalent organic group that may be a monovalent group represented by Formula (1-1), M represents a single bond, a divalent aromatic heterocyclic group, a divalent aromatic hydrocarbon group, an alkenylene group, an alkynylene group, or a divalent group obtained by combining these, p and q each independently represent an integer of 0 to 4, and *'s each independently represent a bonding site to another structure, and M represents an alkyl group that may contain at least one of —O—, —S—, or —NR^{D3}— as a substituent or a monovalent group represented by Formula (1-1), and R^{D3} represents a hydrogen atom or a substituent.

13. The organic semiconductor element according to claim 2,
wherein the repeating unit represented by Formula (1) is a repeating unit represented by any one of Formulae (2) to (5), 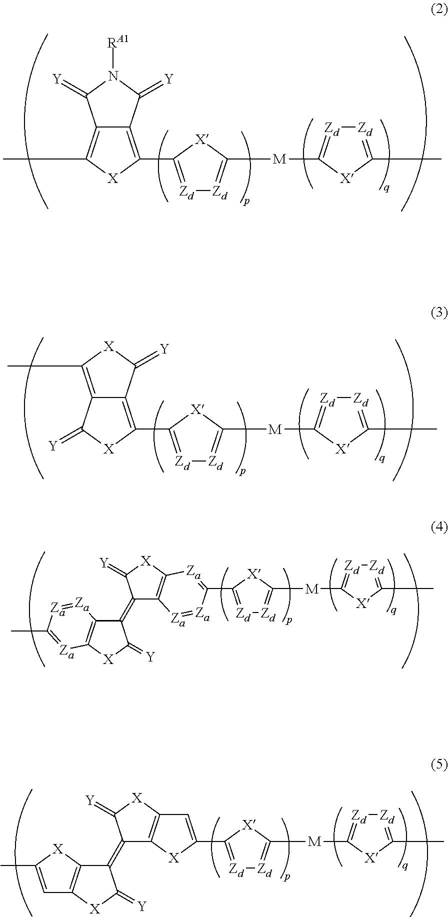
in Formulae (2) to (5), X's each independently represent an O atom, a S atom, a Se atom, or NR^{A1}, Y's each independently represent an O atom or a S atom, Zₐ's each independently represent CR^{A2} or a N atom, R^{A1}'s each independently represent an alkyl group that may contain at least one of —O—, —S—, or —NR^{A3}—, a monovalent group represented by Formula (1-1), or a bonding site to another structure, R^{A2}'s each independently represent an alkyl group that may contain at least one of —O—, —S—, or —NR^{A3}—, a hydrogen atom, a halogen atom, a monovalent group represented by Formula (1-1), or a bonding site to another structure, R^{A3} represents a hydrogen atom or a substituent, X″s each independently represent an O atom, a S atom, a Se atom, or NR^{D1}, Z_{d}'s each independently represent an N atom or CR^{D2}, R^{D1}'s each independently represent a monovalent organic group that may be a monovalent group represented by Formula (1-1), R^{D2}'s each independently represent a hydrogen atom or a monovalent organic group that may be a monovalent group represented by Formula (1-1), M represents a single bond, a divalent aromatic heterocyclic group, a divalent aromatic hydrocarbon group, an alkenylene group, an alkynylene group, or a divalent group obtained by combining these, and p and q each independently represent an integer of 0 to 4, and M represents an alkyl group that may contain at least one of —O—, —S—, or —NR^{D3}— as a substituent or a monovalent group represented by Formula (1-1), and R^{D3} represents a hydrogen atom or a substituent.

14. The organic semiconductor element according to claim 3,
wherein the repeating unit represented by Formula (1) is a repeating unit represented by any one of Formulae (2) to (5), 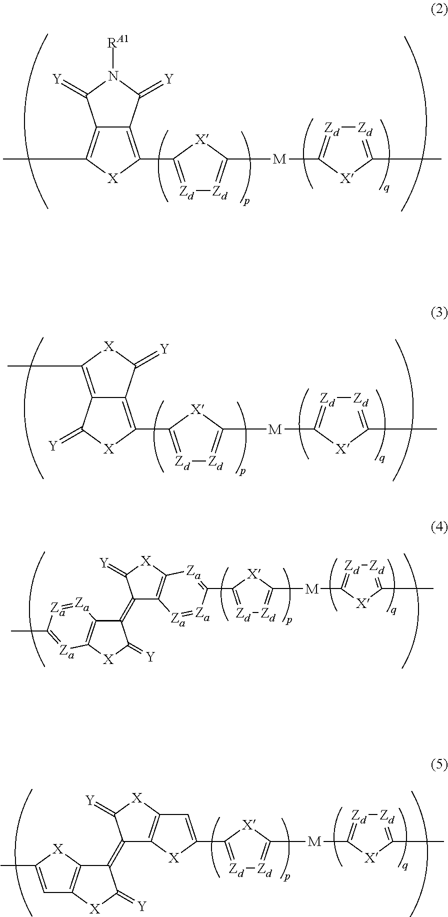
in Formulae (2) to (5), X's each independently represent an Z atom, a S atom, a Se atom, or NR^{A1}, Y's each independently represent an O atom or a S atom, Zₐ's each independently represent CR^{A2} or a N atom, R^{A1}'s each independently represent an alkyl group that may contain at least one of —O—, —S—, or —NR^{A3}—, a monovalent group represented by Formula (1-1), or a bonding site to another structure, R^{A2}'s each independently represent an alkyl group that may contain at least one of —O—, —S—, or —NR^{A3}—, a hydrogen atom, a halogen atom, a monovalent group represented by Formula (1-1), or a bonding site to another structure, R^{A3} represents a hydrogen atom or a substituent, X″s each independently represent an O atom, a S atom, a Se atom, or NR^{D1}, Z_{d}'S each independently represent an N atom or CR^{D2}, R^{D1}'s each independently represent a monovalent organic group that may be a monovalent group represented by Formula (1-1), R^{D2}'s each independently represent a hydrogen atom or a monovalent organic group that may be a monovalent group represented by Formula (1-1), M represents a single bond, a divalent aromatic heterocyclic group, a divalent aromatic hydrocarbon group, an alkenylene group, an alkynylene group, or a divalent group obtained by combining these, and p and q each independently represent an integer of 0 to 4, and M represents an alkyl group that may contain at least one of —O—, —S—, or —NR^{D3}— as a substituent or a monovalent group represented by Formula (1-1), and R^{D3} represents a hydrogen atom or a substituent.

15. The organic semiconductor element according to claim 2,
wherein in Formula (1-1), the number of carbon atoms included in each of R¹, R², and R³ is 2 or greater.

16. The organic semiconductor element according to claim 3,
wherein in Formula (1-1), the number of carbon atoms included in each of R¹, R², and R³ is 2 or greater.

17. The organic semiconductor element according to claim 4,
wherein in Formula (1-1), the number of carbon atoms included in each of R¹, R², and R³ is 2 or greater.

18. The organic semiconductor element according to claim 5,
wherein in Formula (1-1), the number of carbon atoms included in each of R¹, R², and R³ is 2 or greater.

19. The organic semiconductor element according to claim 6,
wherein in Formula (1-1), the number of carbon atoms included in each of R¹, R², and R³ is 2 or greater.
